(19) United States
(12) Patent Application Publication
(10) Pub. No.: US 2019/0198660 A1
(43) Pub. Date: Jun. 27, 2019

(54) SEMICONDUCTOR DEVICE AND ITS MANUFACTURING METHOD

(71) Applicant: RENESAS ELECTRONICS CORPORATION, Tokyo (JP)

(72) Inventor: Tsuyoshi KACHI, Ibaraki (JP)

(21) Appl. No.: 16/184,602

(22) Filed: Nov. 8, 2018

(30) Foreign Application Priority Data
Dec. 22, 2017 (JP) 2017-246438

(51) Int. Cl. H01L 29/78; H01L 29/40; H01L 29/08; H01L 29/06; H01L 29/66

(52) U.S. Cl. CPC H01L 29/7808; H01L 29/7813; H01L 29/404; H01L 29/66734; H01L 29/0882; H01L 29/0619; H01L 29/0865

(57) ABSTRACT

There is provided a semiconductor device and its manufacturing method capable of avoiding generation of a through-current flowing between the drain and source and suppressing the potential fluctuation with time in the field plate electrode. A drain region is arranged on a first surface of a semiconductor substrate, a source region is arranged on a second surface thereof, and a drift region is arranged between the drain region and the source region. The semiconductor substrate has a trench extending from the second surface into the drift region. The field plate electrode is arranged within the trench to be electrically insulated from the drain region and insulated from the drift region oppositely. The Zener diode is electrically coupled between the source region and the field plate electrode. The Zener diode is coupled in a forward direction from the source region to the field plate electrode.

### CROSS-REFERENCE TO RELATED APPLICATIONS

The disclosure of Japanese Patent Application No. 2017-246438 filed on Dec. 22, 2017 including the specification, drawings and abstract is incorporated herein by reference in its entirety.

### BACKGROUND

The invention relates to a semiconductor device and its manufacturing method.

A field plate Metal Oxide Semiconductor Field Effect Transistor (MOSFET) having an insulating gate electrode and a field plate electrode can improve a breakdown voltage while reducing a resistance of a diffusion layer forming a junction, for the field plate electrode relaxes the electric field intensity imposed on the junction in a reverse element state.

In the general field plate MOSFET, like U.S. Pat. No. 7,514,743, the field plate electrode is coupled to a source potential. By providing the field plate electrode with a potential intermediate between the source and drain, the on-resistance can be reduced.

As the simplest method to give the intermediate potential to the field plate electrode, the field plate electrode is drawn to the independent electrode and a power source for generating the intermediate potential between the source and drain is provided. This method, however, is not very preferable because the MOSFET structure and the drive circuit are complicated.

Considering the above defect, there is proposed a method of generating the intermediate potential by adding a simple structure to a MOSFET chip. For example, U.S. Pat. No. 7,893,486 discloses a structure of coupling a resistance between the field plate electrode and the source electrode and coupling a Zener diode between the field plate electrode and the drain electrode. Further, U.S. Pat. No. 4,185,507 discloses a structure of arranging a plurality of field plate electrodes facing a drift region just under the gate.

### SUMMARY

In the structure of U.S. Pat. No. 7,893,486, when the Zener diode exceeds a breakdown voltage, a through-current flows between the drain and source. As the result, a large damage occurs in a resistance coupled to the Zener diode in series. When the resistance is downsized to reduce the damage, the potential of the field plate electrode does not rise enough and a leak current between the drain and source increases disadvantageously.

In the structure of U.S. Pat. Nos. 7,514,743 and 4,185,507, a hot carrier generated when a high voltage is applied to the drain is injected to the insulated field plate electrode. According to this, the potential of the field plate electrode varies over time. According to the fluctuation of the potential in the field plate electrode, the breakdown voltage also fluctuates disadvantageously.

Other objects and novel characteristics will be apparent from the description of the specification and the attached drawings.

A semiconductor device according to one embodiment includes a semiconductor substrate, a first dopant region of a first conductivity type, a second dopant region of the first conductivity type, a drift region of the first conductivity type, a first field plate electrode, and a first Zener diode. The semiconductor substrate has a first surface and a second surface facing each other. The first dopant region is a drain region arranged on the first surface of the semiconductor substrate. The second dopant region is a source region arranged on the second surface of the semiconductor substrate. The drift region is arranged between the first dopant region and the second dopant region within the semiconductor substrate, and it has a lower dopant concentration of the first conductivity type than the first dopant region. The semiconductor substrate has a trench extending from the second surface into the drift region. The first field plate electrode is arranged within the trench to be electrically insulated from the first dopant region and insulated from the drift region oppositely. The first Zener diode is electrically coupled between the second dopant region and the first field plate electrode. The first Zener diode is coupled in a forward direction from the second dopant region to the first field plate electrode.

A semiconductor device according to the other embodiment includes a semiconductor substrate, a first dopant region of a first conductivity type, a second dopant region of a second conductivity type, a drift region of the first conductivity type, a first field plate electrode, and a first Zener diode. The semiconductor substrate has a first surface and a second surface facing each other. The first dopant region is a cathode region arranged on the first surface of the semiconductor substrate. The second dopant region is an anode region arranged on the second surface of the semiconductor substrate. The drift region is arranged between the first dopant region and the second dopant region within the semiconductor substrate and has a lower dopant concentration of the first conductivity type than the first dopant region. The semiconductor substrate has a trench extending from the second surface into the drift region. The first field plate electrode is arranged within the trench to be electrically insulated from the first dopant region and insulated from the drift region oppositely. The first Zener diode is electrically coupled between the second dopant region and the first field plate electrode. The first Zener diode is coupled in a forward direction from the second dopant region to the first field plate electrode.

A manufacturing method of a semiconductor device according to one embodiment includes the following steps.

A first dopant region of a first conductivity type is formed as a drain region on a first surface of a semiconductor substrate having the first surface and a second surface facing each other. A drift region of the first conductivity type having a lower dopant concentration of the first conductivity type than the first dopant region is formed on the first dopant region at the side of the second surface within the semiconductor substrate. A trench extending from the second surface into the drift region is formed in the semiconductor substrate. A first field plate electrode is formed within the trench to be electrically insulated from the first dopant region and insulated from the drift region oppositely. A second dopant region of the first conductivity type is formed as a source region on the second surface of the semiconductor substrate to sandwich the drift region with the first dopant region. A Zener diode is electrically coupled between the second dopant region and the first field plate electrode. The Zener diode is formed to be coupled in the forward direction from the second dopant region to the first field plate electrode.

According to the above embodiments, it is possible to realize a semiconductor device and its manufacturing method capable of avoiding generation of a through-current and suppressing a potential fluctuation over time in the field plate electrode.

### BRIEF DESCRIPTION OF THE DRAWINGS

FIG. 1 is a cross-sectional diagram conceptually showing the structure of a semiconductor device of this disclosure.

FIG. 2 is a top plan view showing the structure of a semiconductor device in a comparison example.

FIG. 3 is a cross-sectional diagram conceptually showing the structure of a semiconductor device according to a first embodiment.

FIG. 4 is a top plan view showing the structure of the semiconductor device according to the first embodiment.

FIG. 5 is an enlarged top plan view showing the region RA of FIG. 4 in an enlarged way.

FIG. 6 is a schematic cross-sectional view taken along the line VI-VI in FIG. 5.

FIG. 7 is a schematic cross-sectional view taken along the line VII-VII in FIG. 5.

FIG. 8 is a schematic cross-sectional view taken along the line VIII-VIII in FIG. 5.

FIG. 9 is an enlarged top plan view showing the region RB of FIG. 4 in an enlarged way.

FIG. 10 is a schematic cross-sectional view taken along the line X-X in FIG. 9.

FIG. 11 is a cross-sectional view showing measurement of each unit of the semiconductor device according to the first embodiment.

FIG. 12 is a cross-sectional view showing a first process of a manufacturing method of the semiconductor device according to the first embodiment.

FIG. 13 is a cross-sectional view showing a second process of the above manufacturing method according to the first embodiment.

FIG. 14 is a cross-sectional view showing a third process of the above manufacturing method according to the first embodiment.

FIG. 15 is a cross-sectional view showing a fourth process of the above manufacturing method according to the first embodiment.

FIG. 16 is a cross-sectional view showing a fifth process of the above manufacturing method according to the first embodiment.

FIG. 17 is a cross-sectional view showing a sixth process of the above manufacturing method according to the first embodiment.

FIG. 18 is a cross-sectional view showing a seventh process of the above manufacturing method according to the first embodiment.

FIG. 19 is a cross-sectional view showing an eighth process of the above manufacturing method according to the first embodiment.

FIG. 20 is a cross-sectional view showing a ninth process of the above manufacturing method according to the first embodiment.

FIG. 21 is a cross-sectional view showing a tenth process of the above manufacturing method according to the first embodiment.

FIG. 22 is a cross-sectional view showing an eleventh process of the above manufacturing method according to the first embodiment.

FIG. 23 is a cross-sectional view showing a twelfth process of the above manufacturing method according to the first embodiment.

FIG. 24 is a cross-sectional view showing a thirteenth process of the above manufacturing method according to the first embodiment.

FIG. 25 is a cross-sectional view showing a fourteenth process of the above manufacturing method according to the first embodiment.

FIG. 26 is a cross-sectional diagram conceptually showing the structure of a semiconductor device according to a second embodiment, corresponding to the cross section taken along the line XXVI-XXVI in FIG. 27.

FIG. 27 is a top plan view showing the structure of the semiconductor device according to the second embodiment, in a way of enlarging the region corresponding to the region RA in FIG. 2.

FIG. 28 is a schematic cross-sectional view taken along the line XXVIII-XXVIII in FIG. 27.

FIG. 29 is a schematic cross-sectional view taken along the line XXIX-XXIX in FIG. 27.

FIG. 30 is a cross-sectional view showing a first process of a manufacturing method of the semiconductor device according to the second embodiment.

FIG. 31 is a cross-sectional view showing a second process of the above manufacturing method according to the second embodiment.

FIG. 32 is a cross-sectional view showing a third process of the above manufacturing method according to the second embodiment.

FIG. 33 is a cross-sectional diagram conceptually showing the structure of a semiconductor device according to a third embodiment, corresponding to the cross section taken along the line XXXIII-XXXIII in FIG. 34.

FIG. 34 is a top plan view showing the structure of the semiconductor device according to the third embodiment, in a way of enlarging the region corresponding to the region RA in FIG. 2.

FIG. 35 is a schematic cross-sectional view taken along the line XXXIII-XXXIII and the line XXXV-XXXV in FIG. 34.

FIG. 36 is a cross-sectional view showing a first process of a manufacturing method of the semiconductor device according to the third embodiment.

FIG. 37 is a cross-sectional view showing a second process of the above manufacturing method according to the third embodiment.

FIG. 38 is a cross-sectional view showing a third process of the above manufacturing method according to the third embodiment.

FIG. 39 is a cross-sectional view showing a fourth process of the above manufacturing method according to the third embodiment.

FIG. 40 is a cross-sectional view showing a fifth process of the above manufacturing method according to the third embodiment.

FIG. 41 is a cross-sectional view showing a sixth process of the above manufacturing method according to the third embodiment.

FIG. 42 is a cross-sectional view showing a seventh process of the above manufacturing method according to the third embodiment.

FIG. 43 is a cross-sectional view showing an eighth process of the above manufacturing method according to the third embodiment.

FIG. 44A is a view showing the potential distribution within a cell when a voltage is applied to the drain according to the second embodiment and FIG. 44B is a view showing the potential distribution within a cell when the same voltage is applied to the drain according to the third embodiment.

FIG. 45 is a view showing electric field intensity in respective portions along the line L1 in FIG. 44A and the line L2 in FIG. 44B.

FIG. 46 is a cross-sectional diagram conceptually showing the structure of a semiconductor device according to a fourth embodiment.

FIG. 47 is a cross-sectional diagram conceptually showing the structure of a semiconductor device in a modified example according to the fourth embodiment.

### DETAILED DESCRIPTION

Hereinafter, a semiconductor device according to one embodiment of this disclosure will be described based on the drawings.

(Semiconductor Device of this Disclosure)

At first, a structure of a semiconductor device according to the disclosure will be described.

A semiconductor device in the disclosure is, for example, a field plate MOS transistor. The semiconductor device in the disclosure is not restricted to the field plate MOS transistor but may be a diode or Insulated Gate Bipolar Transistor (IGBT) having a field plate electrode. The structure will be described taking a field plate MOS transistor as an example.

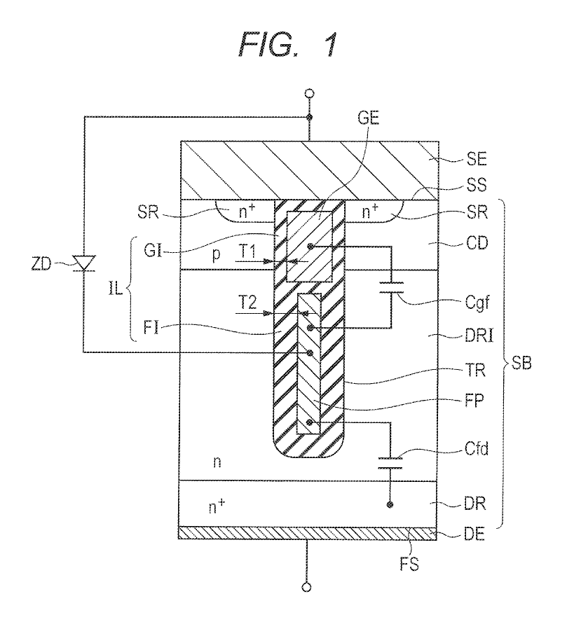

As shown in FIG. 1, a field plate MOS transistor includes a MOS transistor and a field plate electrode FP (first field plate electrode).

The MOS transistor mainly includes a drain region DR (first dopant region), a drift region DRI, a channel region CD, a source region SR (second dopant region) arranged within the channel region CD, a gate insulation layer GI, and a gate electrode GE.

The MOS transistor is formed in a semiconductor substrate SB. The semiconductor substrate SB has a first surface FS and a second surface SS facing each other.

The drain region DR is an n-type dopant region (n⁺ dopant region), which is arranged on the first surface FS of the semiconductor substrate SB. The source region SR is an n-type dopant region (n⁺ dopant region), which is arranged on the second surface SS of the semiconductor substrate SB.

The drift region DRI is arranged between the drain region DR and the source region SR within the semiconductor substrate SB. The drift region DRI is an n-type dopant region, having a lower n-type dopant concentration than that of the drain region DR and the source region SR. The drift region DRI is in contact with the drain region DR.

The channel region CD is arranged between the source region SR and the drift region DRI within the semiconductor substrate SB. This channel region CD is arranged to sandwich the drift region DRI between the drain region DR and itself. The channel region CD is arranged on the second surface SS to surround the source region SR. The channel region CD is a p-type dopant region, forming a pn junction with each of the source region SR and the drift region DRI.

The semiconductor substrate SB has a trench TR extending from the second surface SS into the drift region DRI. The drift region DRI, the channel region CD, and the source region SR are in contact with the lateral wall of the trench TR.

The gate electrode GE is arranged within the trench TR. The gate electrode GE faces the channel region CD with the gate insulation layer GI intervening therebetween. Thus, the gate electrode GE is insulated from the channel region CD oppositely.

The drain electrode DE is arranged on the first surface FS of the semiconductor substrate SB. The drain electrode DE is in contact with the drain region DR, to be electrically coupled to the drain region DR. The source electrode SE is arranged on the second surface SS of the semiconductor substrate SB. The source electrode SE is in contact with each of the source region SR and the channel region CD, to be electrically coupled to the source region SR and the channel region CD.

The field plate electrode FP is arranged within the trench TR. The field plate electrode FP faces the drift region DRI with the field plate insulating layer FI intervening therebetween. Thus, the field plate electrode FP is insulated from the drift region DRI oppositely. The field plate electrode FP is positioned at the side nearer to the first surface FS than the gate electrode GE, within the trench TR. The field plate electrode FP is electrically insulated from the drain region DR.

The field plate electrode FP and the gate electrode GE are arranged within the same trench TR. The thickness T1 of the gate insulation layer GI is thinner than the thickness T2 of the field plate insulating layer FI. The gate insulation layer GI and the field plate insulating layer FI are included in the insulating layer IL within the trench TR.

The semiconductor device in the disclosure has a Zener diode ZD (first Zener diode). The Zener diode ZD is electrically coupled between the source region SR and the field plate electrode FP. The Zener diode ZD is electrically coupled to the source electrode SE, and further electrically coupled to both the source region SR and the channel region CD through the source electrode SE.

The Zener diode ZD is coupled in a forward direction from the source electrode SE (or the source region SR) to the field plate electrode FP. Specifically, the anode of the Zener diode ZD is electrically coupled to the source electrode SE (or the source region SR) and the cathode thereof is electrically coupled to the field plate electrode FP.

The breakdown voltage (Zener breakdown voltage) of the Zener diode ZD is set at the breakdown voltage and less between the drain and source of the MOS transistor. The parasitic capacitance of the Zener diode ZD is set at a value fairly smaller than the gate and field plate capacitance Cgf and the field plate and drain capacitance Cfd.

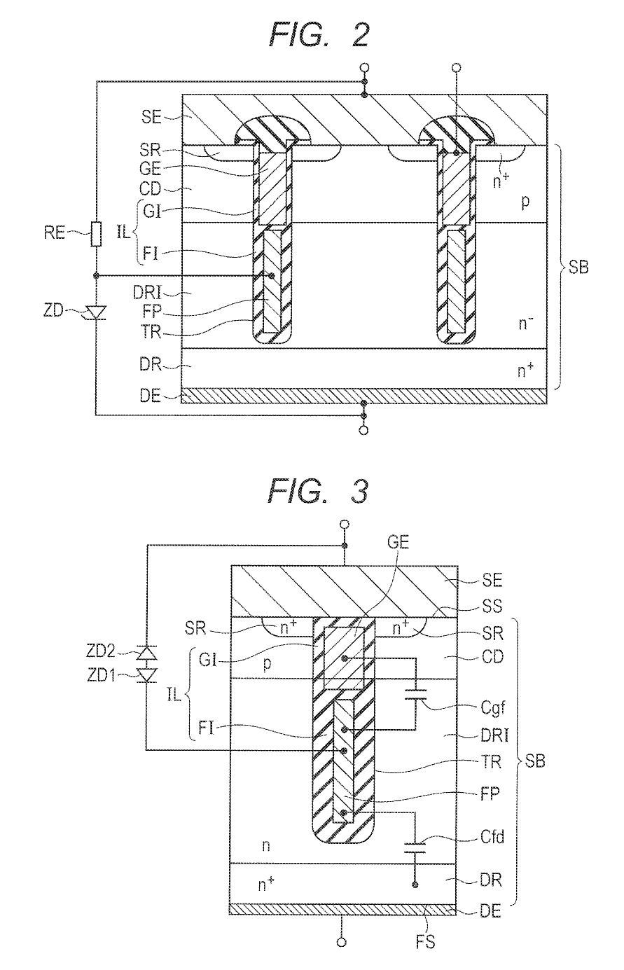

The effects of the semiconductor device in the disclosure will be described in contrast with a comparison example shown in FIG. 2.

As shown in FIG. 2, in the semiconductor device of the comparison example, the Zener diode ZD is electrically coupled between the field plate electrode FP and the drain region DR and a resistance RE is electrically coupled between the field plate electrode FP and the source electrode SE (or the source region SR). The structure of the comparison example other than this is substantially the same as the structure of the semiconductor device in the disclosure shown in FIG. 1; therefore, the same reference numerals are attached to the same elements and their description is not repeated.

In the structure of the comparison example shown in FIG. 2, when the Zener diode ZD exceeds the Zener breakdown voltage, a through-current flows between the drain region DR and the source electrode SE (or the source region SR). Therefore, a great damage occurs in the resistance RE electrically coupled to the Zener diode ZD in series. When the resistance RE is downsized to reduce this damage, the potential of the field plate electrode FP does not rise fully, and moreover, a leak current between the drain region DR and the source region SR increases.

On the contrary, according to the semiconductor device of the disclosure, as shown in FIG. 1, the field plate electrode FP is electrically coupled to the drain region DR. Therefore, a through-current never flows between the drain region DR and the source region SR of the MOS transistor.

When a hot carrier (electron) generated at a time of applying a high voltage to the drain region DR is injected in the field plate electrode FP, in a structure of electrically insulating the field plate electrode FP from the other elements, the potential of the field plate electrode FP varies over time. According to this, the potential of the field plate electrode FP fluctuates and accordingly, the breakdown voltage also fluctuates.

On the contrary, according to the semiconductor device of this disclosure, as shown in FIG. 1, the field plate electrode FP is electrically coupled to the source electrode SE (or the source region SR) through the Zener diode ZD. Further, the Zener diode ZD is provided in the forward direction from the source electrode SE (or the source region SR) to the field plate electrode FP. According to this, even when a hot carrier (electron) is injected to the field plate electrode FP, the hot carrier is discharged to the source electrode SE (or the source region SR) as a leak current of the Zener diode ZD. As the result, the potential of the field plate electrode FP does not fluctuate over time according to the hot carrier.

According to the semiconductor device of the disclosure, when the drain region DR is biased, the potential (Vfp) of the field plate electrode FP rises according to the capacitances Cfd and Cgf (Vfp=Vds×Cfd/(Cgf+Cfd); Vds is the voltage between the drain and source).

According to the semiconductor device of the disclosure, the potential difference between the source and field plate does not rise more than the Zener breakdown voltage. Thus, it is possible to avoid a dielectric breakdown between the gate and field plate caused by an excessive voltage imposed on the field plate electrode FP.

### First Embodiment

A structure of a semiconductor device according to a first embodiment will be described using FIG. 3.

As shown in FIG. 3, the structure of the semiconductor device according to the first embodiment is different from that of the semiconductor device in the disclosure shown in FIG. 1, in that two Zener diodes ZD1 and ZD2 are electrically coupled between the field plate electrode FP and the source electrode SE (or the source region SR).

The two Zener diodes ZD1 and ZD2 are coupled in series between the field plate electrode FP and the source electrode SE (or the source region SR). The Zener diode ZD1 is coupled in the forward direction from the source electrode SE (or the source region SR) to the field plate electrode FP. The Zener diode ZD2 is coupled in the backward direction of the above; from the field plate electrode FP to the source electrode SE (or the source region SR).

The cathode of the Zener diode ZD1 is electrically coupled to the field plate electrode FP. The anode of the Zener diode ZD1 is electrically coupled to the anode of the Zener diode ZD2. The cathode of the Zener diode ZD2 is electrically coupled to the source region SR.

The structure of the embodiment other than the above is substantially the same as that shown in FIG. 1; therefore, the same reference numerals are attached to the same elements and their description is not repeated.

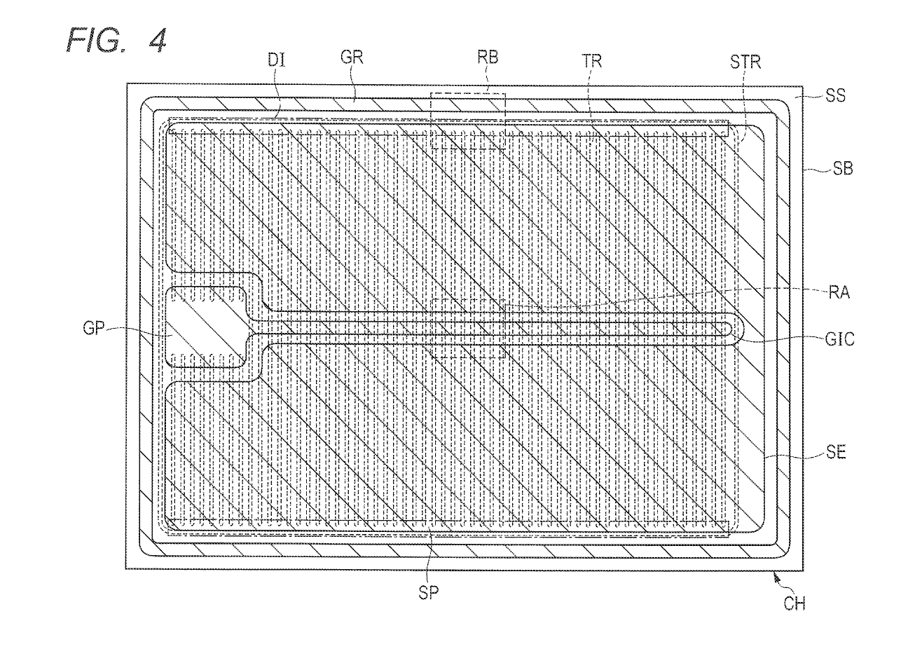

The concrete structure of the semiconductor device according to the embodiment will be described using FIGS. 4 to 11.

As shown in FIG. 4, the semiconductor device in the embodiment is, for example, a semiconductor chip CH. The semiconductor device in the embodiment is not restricted to the semiconductor chip CH but may be in a state of a semiconductor wafer before being cut into a semiconductor chip or may be a semiconductor package after sealing a semiconductor chip with resin, or further may be a semiconductor module combined with another device.

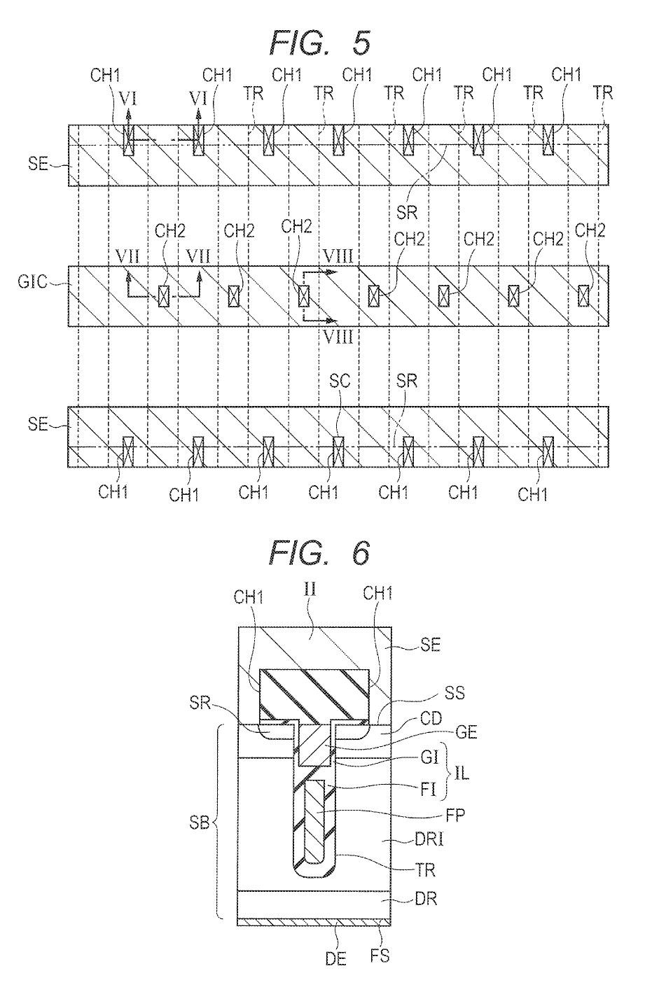

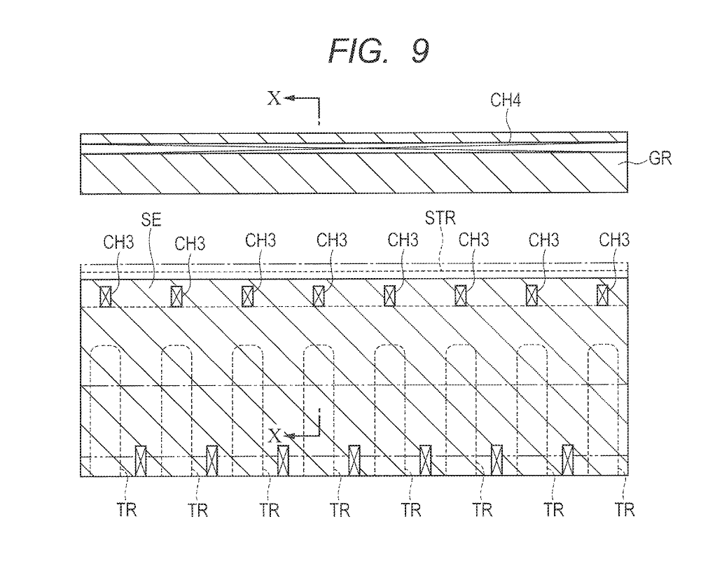

FIG. 4 is a top plan view viewed from the side of the second SS of the semiconductor substrate SB, FIG. 5 is an enlarged view of the region RA in FIG. 4, and FIG. 9 is an enlarged view of the region RB in FIG. 4. In plan views shown in FIGS. 4, 5, and 9, a field plate MOS transistor is arranged in a center of the second surface SS of the semiconductor substrate SB.

A plurality of trenches TR are arranged on the second surface SS of the semiconductor substrate SB, in the arrangement region of the field plate MOS transistor. The respective trenches TR mutually extend in parallel in a straight line shape.

A source electrode trench STR is arranged to surround the arrangement region of the plural trenches TR in plan view.

A gate wiring layer GIC and the source electrode SE are arranged on the second surface SS of the semiconductor substrate SB, in the arrangement region of the field plate MOS transistor.

The gate wiring layer GIC extends in a direction orthogonal to the extending direction of the trench TR, in plan view. The source electrode SE is arranged to be positioned in each of the regions divided by the gate wiring layer GIC, in plan view.

A guard ring GR is arranged to surround the arrangement region of the field plate MOS transistor in plan view. The guard ring GR extends around the whole periphery without a break. Thus, the guard ring GR surrounds the gate wiring layer GIC and the source electrode SE in plan view.

The gate wiring layer GIC, the source electrode SE, and the guard ring GR are formed mutually separated from one identical conductive layer.

Plan view means a visual point when the semiconductor chip CH (semiconductor device) is viewed in a direction orthogonal to the second surface SS of the semiconductor substrate SB.

As shown in FIG. 6, the structure of the MOS transistor and the field plate electrode FP in the cross section is substantially the same as that shown in FIG. 3; therefore, the same reference numerals are attached to the same elements and their description is not repeated.

An interlayer insulating layer II is arranged on the second surface SS of the semiconductor substrate SB. The interlayer insulating layer II covers the gate electrode GE. The interlayer insulating layer II is provided with a contact hole CH1. The contact hole CH1 ranges from the top surface of the interlayer insulating layer II to the source region SR and the channel region CD.

The source electrode SE is arranged on the interlayer insulating layer II. The source electrode SE is in contact with the source region SR and the channel region CD through the contact hole CH1. According to this, the source electrode SE is electrically coupled to the source region SR and the channel region CD through the contact hole CH1.

The drain electrode DE is arranged on the first surface FS of the semiconductor substrate SB. The drain electrode DE is in contact with the drain region DR, hence to be electrically coupled to the drain region DR.

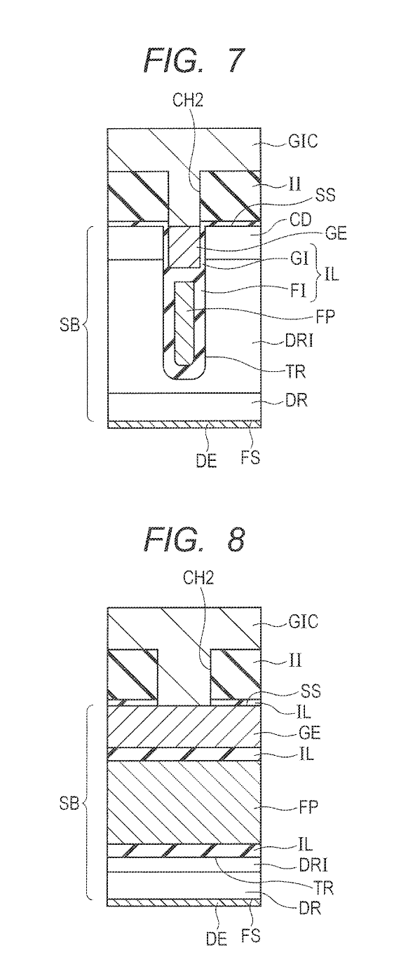

As shown in FIGS. 7 and 8, in this cross section, a contact hole CH2 is formed on the interlayer insulating layer II arranged on the second surface SS of the semiconductor substrate SB. The contact hole CH2 is in touch with the gate electrode GE from the top surface of the interlayer insulating layer II.

The gate wiring layer GIC is arranged on the interlayer insulating layer II. The gate wiring layer GIC is in contact with the gate electrode GE through the contact hole CH2. According to this, the gate wiring layer GIC is electrically coupled to the gate electrode GE through the contact hole CH2.

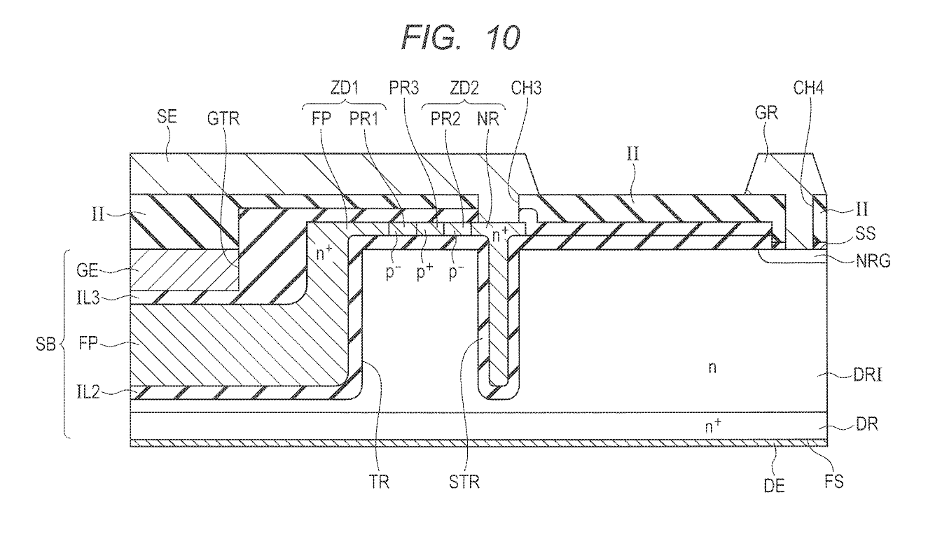

As shown in FIG. 10, in this cross section, the two Zener diodes ZD1 and ZD2 are arranged. The two Zener diodes ZD1 and ZD2 are electrically coupled between the field plate electrode FP and the source electrode SE.

The Zener diode ZD1 includes an n⁺ region FP as the cathode and a p⁻ region PR1 as the anode. The n⁺ region FP and the p⁻ region PR1 of the Zener diode ZD1 form a pn junction.

The Zener diode ZD2 includes an n⁺ region NR as the cathode and a p⁻ region PR2 as the anode. The n⁺ region NR and the p⁻ region PR2 form a pn junction.

A p⁺ region PR3 is arranged between the p⁻ region PR1 of the Zener diode ZD1 and the p⁻ region PR2 of the Zener diode ZD2. The p⁺ region PR3 is in contact with the p⁻ region PR1 and the p⁻ region PR2.

The above two Zener diodes ZD1 and ZD2 and the field plate electrode FP are formed in the same conductive layer. The conductive layer where the Zener diodes ZD1 and ZD2 and the field plate electrode FP are formed is made of, for example, dopant introduced polycrystalline silicon (doped polysilicon).

Specifically, by introducing the n-type dopant into the polycrystalline silicon, the field plate electrode FP, the n⁺ region FP, and the n⁺ region NR are formed. Especially, the field plate electrode FP and the n⁺ region FP are formed by the common n⁺ region.

Further, the doped polysilicon with the p-type dopant introduced to the polycrystalline silicon forms the p⁻ region PR1, the p⁻ region PR2, and the p⁺ region PR3. The p-type dopant concentration in the p⁻ region PR1 and the p⁻ region PR2 is lower than the p-type dopant concentration in the p⁺ region PR3.

The conductive layer portion where the above two Zener diodes ZD1 and ZD2 are formed is arranged on the second surface SS of the semiconductor substrate SB through the insulating layer IL. In other words, the n⁺ region FP and p⁻ region PR1 of the Zener diode ZD1, the n⁺ region NR and p⁻ region PR2 of the Zener diode ZD2, the p⁺ region PR3 are arranged on the second surface SS of the semiconductor substrate SB through the insulating layer IL.

The source electrode trench STR is formed on the second surface SS of the semiconductor substrate SB. The source electrode trench STR extends toward the side of the first surface FS within the drift region DRI. The n⁺ region NR as the cathode of the Zener diode ZD2 is embedded within the source electrode trench STR. An insulating layer IL2 is arranged between the n⁺ region NR and the wall surface of the source electrode trench STR. Thus, the n⁺ region NR is insulated from the drift region DRI oppositely and also works as the source trench electrode. The insulating layer IL2 is also formed on the wall surface of the trench TR, to electrically insulate the field plate electrode FP from the drift region DRI.

The conductive layer portion where the above two Zener diodes ZD1 and ZD2 are formed is covered with the insulating layer IL3. A concave portion GTR is formed in the insulating layer IL3 within the trench TR. The gate electrode GE is arranged within the concave portion GTR.

The interlayer insulating layer II is arranged to cover the gate electrode GE and the insulating layer IL3. A contact hole CH3 is formed penetrating the insulating layer IL3 from the top surface of the interlayer insulating layer II and arriving at the n⁺ region NR. The source electrode SE is electrically coupled to the n⁺ region NR through the contact hole CH3.

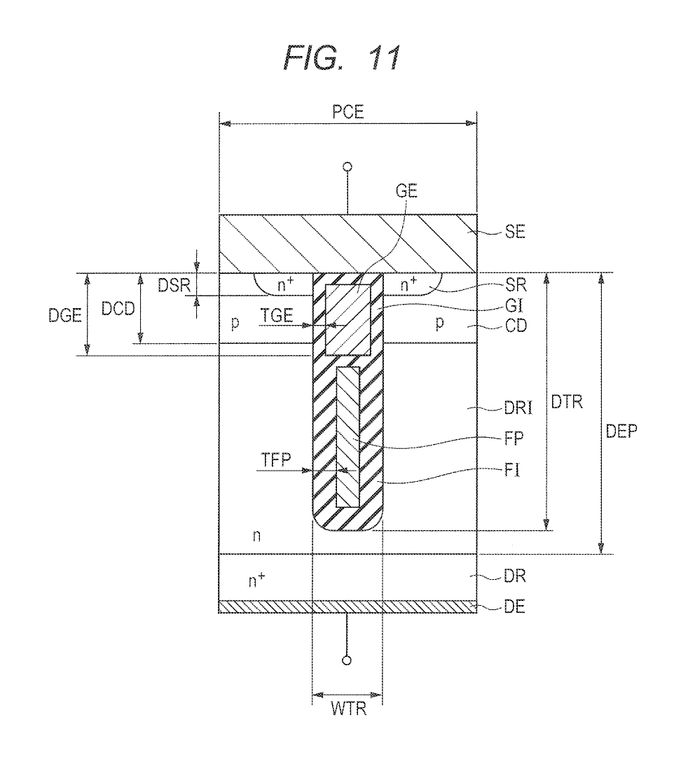

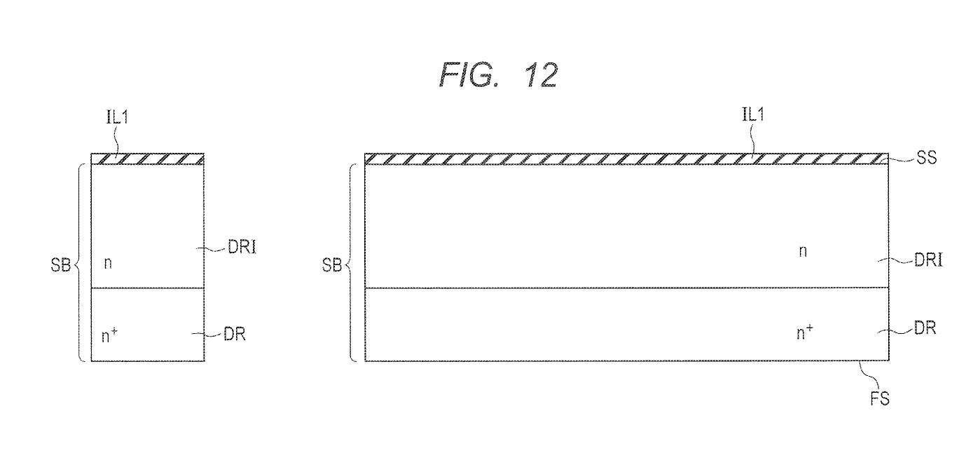

As shown in FIG. 11, the thickness DEP of the epitaxial layer in the semiconductor substrate SB (the total thickness of the drift region DRI and the channel region CD) is, for example, 7 μm and less. The depth DCD of the channel region CD is, for example, 1.0 μm and less. The depth DSR of the source region SR is, for example, 0.3 μm and less.

The depth DTR of the trench TR is, for example, 6 μM and less. The width WTR of the trench TR is, for example, 1.3 μM and less. The depth DGE of the gate electrode GE is, for example, 1.2 μm and less. The thickness TFP of the field plate insulating layer FI is, for example, 550 nm and less. The thickness TGE of the gate insulation layer GI is, for example, 50 nm and less.

Next, a manufacturing method of the semiconductor device according to the embodiment will be described using FIGS. 12 to 25.

As shown in FIG. 12, an n-type silicon DRI is formed on the n⁺ silicon substrate DR according to the epitaxial growth. As the result, there is formed a semiconductor substrate SB having the first surface FS and the second surface SS facing each other, the n⁺ drain region DR on the first surface FS, and the n-type drift region DRI on the second surface SS. A silicon oxide film IL1 (insulating layer) with a predetermined thickness is formed on the first surface FS of the semiconductor substrate SB according to the thermal oxidation.

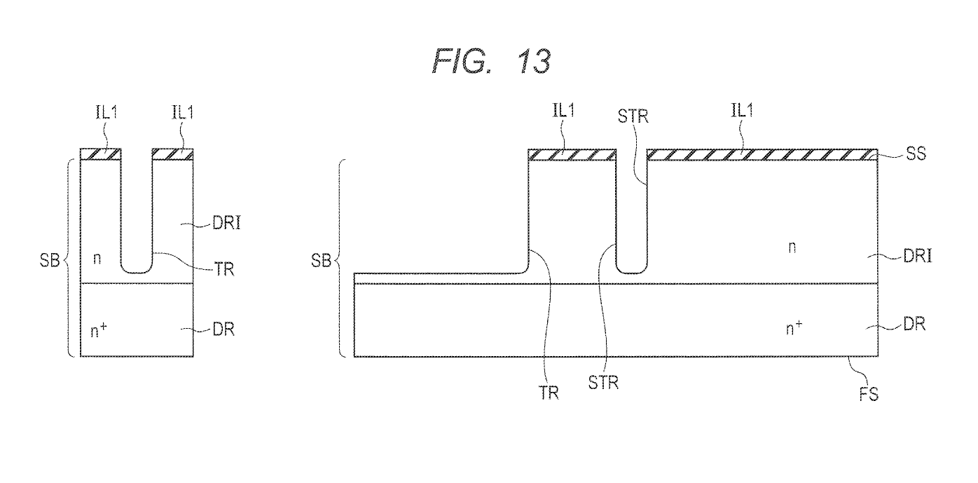

As shown in FIG. 13, a resist pattern (not illustrated) having a trench pattern according to the photoengraving technique is formed on the oxide film IL1. With this resist pattern as a mask, the oxide film IL1 is patterned according to the dry etching. After removing the resist pattern, a trench TR and a source electrode trench STR are formed on the semiconductor substrate SB according to the dry etching with the oxide film IL1 used as the mask. Then, the oxide film IL1 is removed according to the wet etching with hydrofluoric (HF) acid solution.

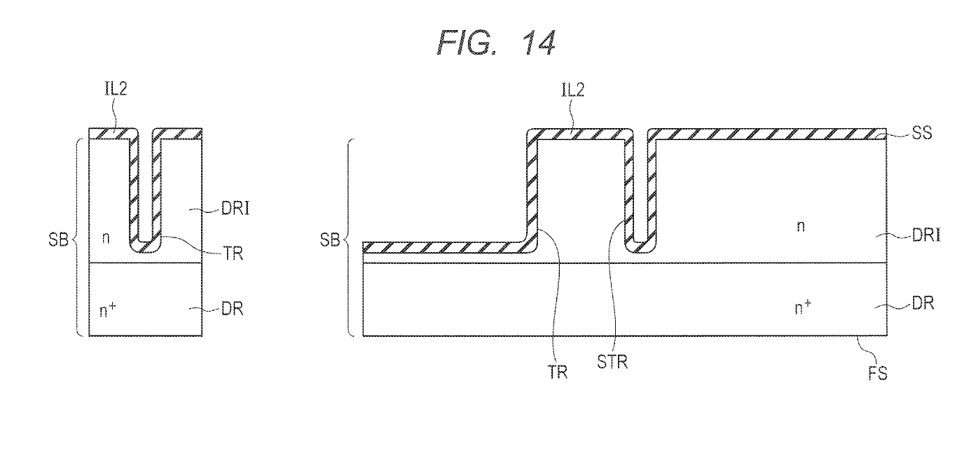

As shown in FIG. 14, the insulating layer IL2 made of silicon oxide film is formed on the second surface SS of the semiconductor substrate SB and the wall surface of the trench TR and the source electrode trench STR according to the thermal oxidation after the above wet etching.

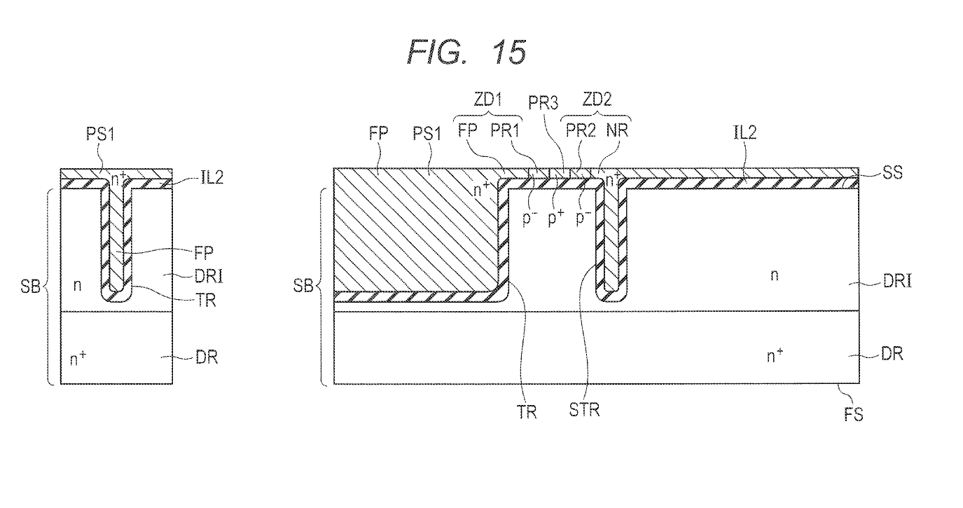

As shown in FIG. 15, a polycrystalline silicon layer PS1 that will be the field plate electrode FP is deposited on the insulating layer IL2 according to the Chemical Vapor Deposition (CVD). The n-type dopant is introduced to the portions of the field plate electrode FP, the n⁺ region FP of the Zener diode ZD1, and the n⁺ region NR of the Zener diode ZD2, of the polycrystalline silicon layer PS1, according to the ion implantation.

Further, the p-type dopant is introduced to the portions of the p⁻ region PR1 of the Zener diode ZD1, the p⁻ region PR2 of the Zener diode ZD2, and the p⁺ region PR3, of the polycrystalline silicon layer PS1, according to the ion implantation.

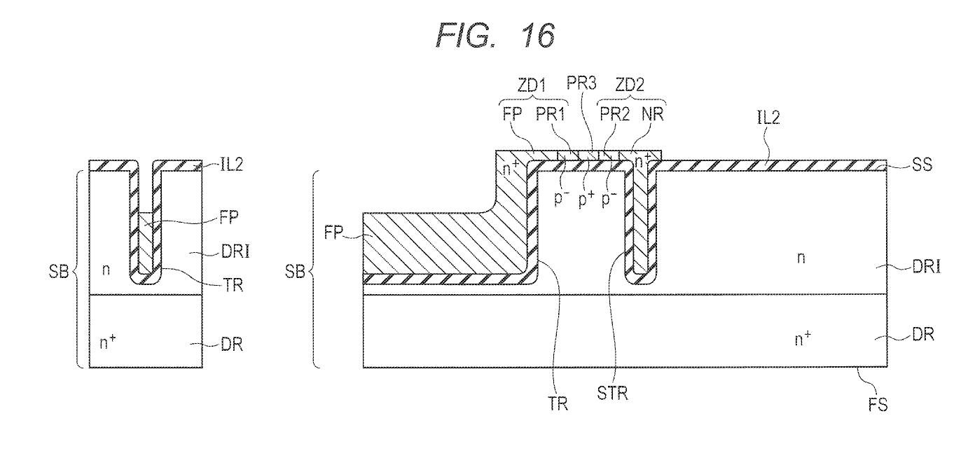

As shown in FIG. 16, a resist pattern (not illustrated) to cover the portion corresponding to the Zener diodes ZD1 and ZD2 of the n-type and p-type dopant-injected polycrystalline silicon layer PS1 and the portion corresponding to the trench source electrode, is formed according to the photoengraving technique. With this resist pattern used as a mask, the polycrystalline silicon layer PS1 is dry-etched. The polycrystalline silicon layer PS1 within the trench TR corresponding to the portion that will form the field plate electrode FP and the portion that will form the Zener diodes ZD1 and ZD2 is left by adjusting the etching amount. Thereafter, the resist pattern is removed, for example, according to the asking.

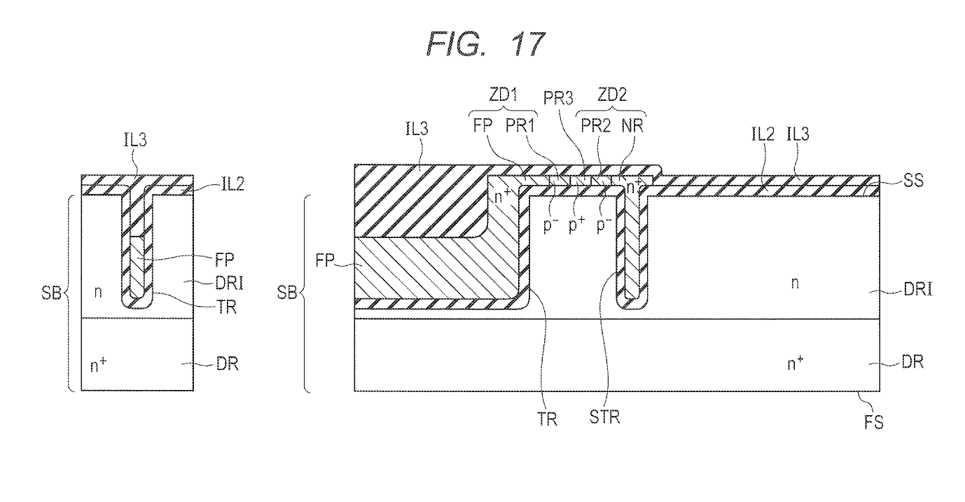

As shown in FIG. 17, the insulating layer IL3 made of oxide film is deposited on the insulating layer IL2 to cover the polycrystalline silicon layer PS1 according to the CVD. Here, the inside of the trench TR is fully filled with the insulating layer IL3.

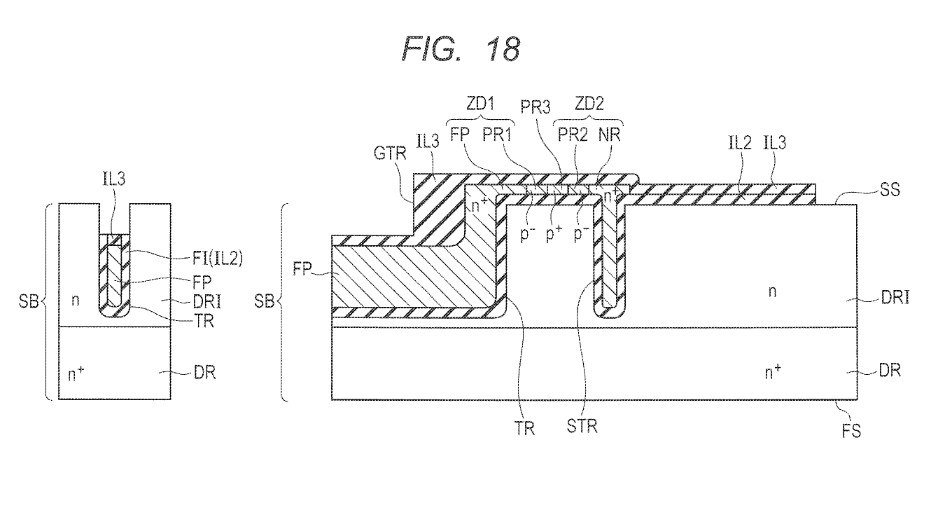

As shown in FIG. 18, a resist pattern (not illustrated) to cover the portion other than the portion that will be the trench gate electrode and the outer peripheral guard ring contact is formed according to the photoengraving technique. With this resist pattern used as a mask, the insulating layer IL3 is dry-etched. The insulating layer IL3 is left on the field plate electrode FP within the trench TR, by adjusting the etching amount. According to this, the concave portion GTR is formed in the insulating layer IL3 within the trench TR. Further, according to the above dry etching, in the portion that forms the guard ring contact, the insulating layers IL2 and IL3 are removed, to bare the second surface SS of the semiconductor substrate SB. Then, the resist pattern is removed, for example, according to the asking.

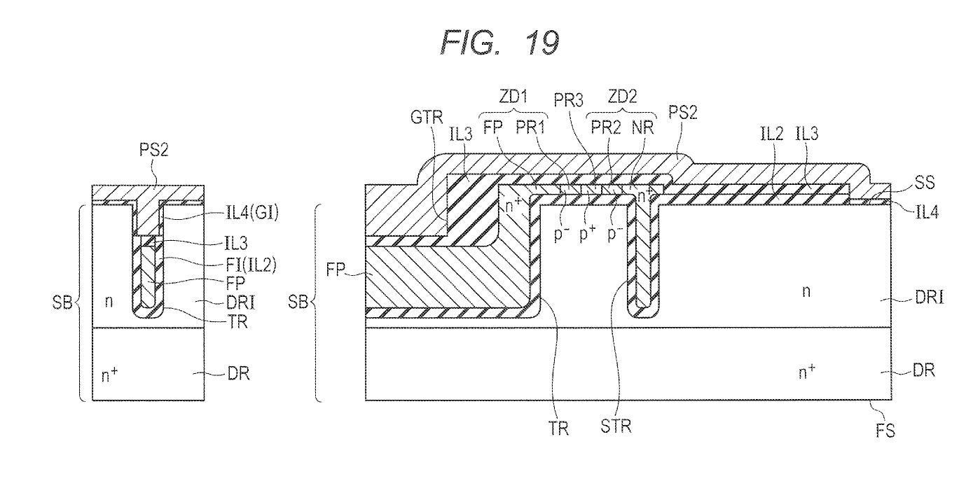

As shown in FIG. 19, the second surface SS of the semiconductor substrate SB and the wall surface of the trench TR are oxidized according to the thermal oxidation and an insulating layer IL4 made of silicon oxide film is formed. The portion of the insulating layer IL4 formed on the wall surface of the trench TR works as the gate insulation layer GI. Then, a polycrystalline silicon layer PS2 is formed to fill the trench TR and cover the insulating layers IL3 and IL4. Thereafter, the polycrystalline silicon layer PS2 is dry-etched.

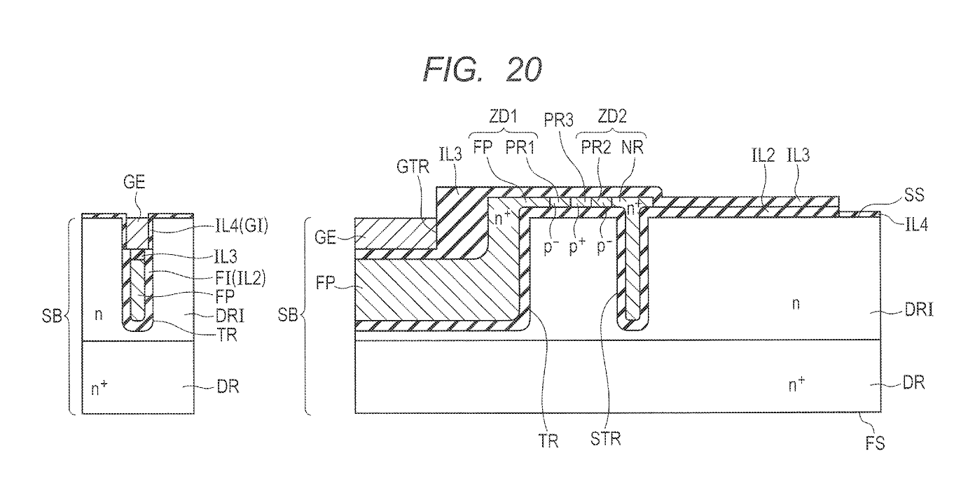

As shown in FIG. 20, the gate electrode GE is formed from the polycrystalline silicon layer PS2, filling the trench TR (being embedded within the concave portion GTR), according to the above dry etching.

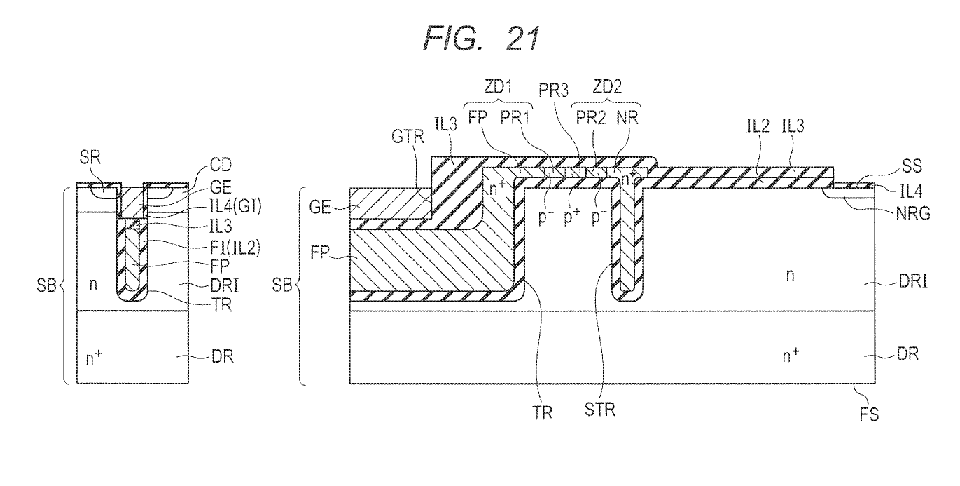

As shown in FIG. 21, a resist pattern (not illustrated) is formed according to the photoengraving technique, and the p-type dopant is injected to the second surface SS of the semiconductor substrate SB according to the ion implantation with the resist pattern used as a mask. According to this, the channel region CD is formed on the second surface SS of the semiconductor substrate SB. Then, the resist pattern is removed, for example, according to the ashing.

Then, another resist pattern (not illustrated) is formed according to the photoengraving technique, and the n-type dopant is injected to the second surface SS of the semiconductor substrate SB with this resist pattern used as a mask according to the ion implantation. Thus, the source region SR and the dopant region NRG for the n⁺ guard ring are formed on the second surface SS of the semiconductor substrate SB. Then, this resist pattern is also removed, for example, according to the ashing.

Annealing for dopant activation is performed after the resist pattern is removed.

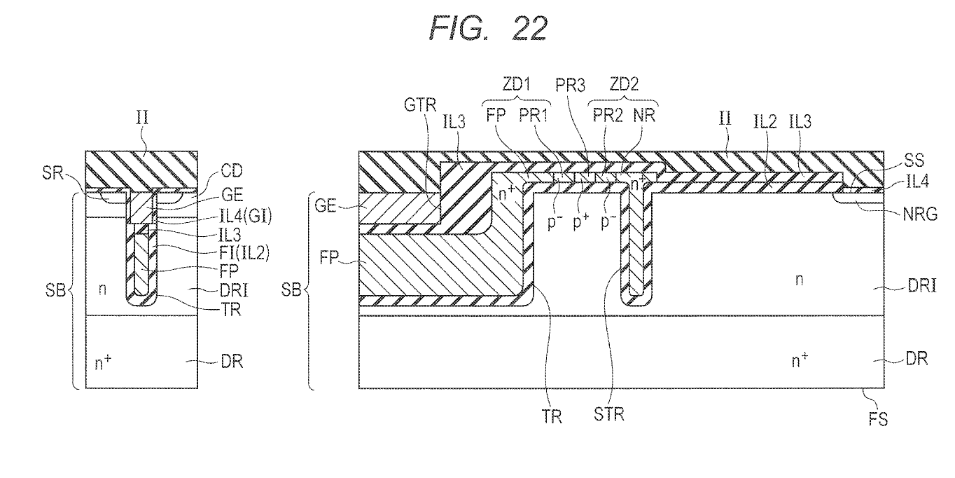

As shown in FIG. 22, the interlayer insulating layer II made of phosphorus glass is deposited on the whole surface of the second surface SS of the semiconductor substrate SB. Then, the surface of the interlayer insulating layer II is flattened according to the Chemical Mechanical Polishing (CMP).

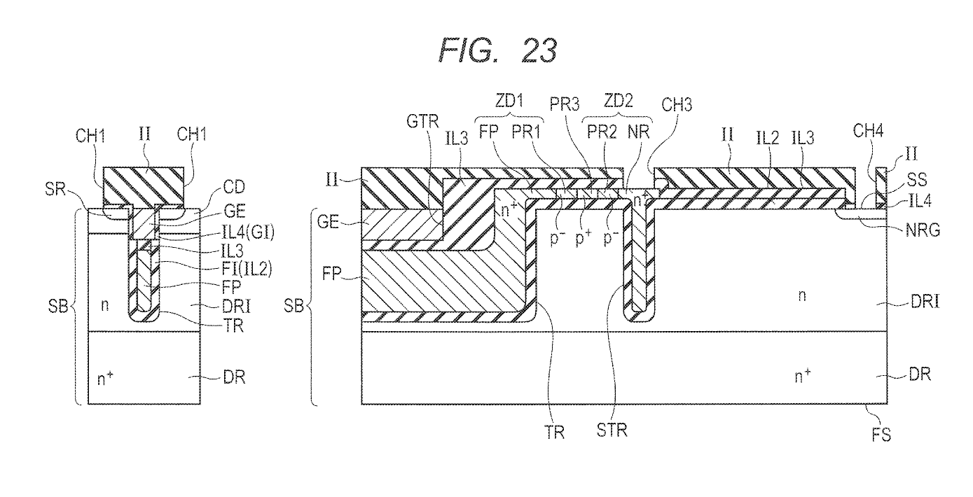

As shown in FIG. 23, a resist pattern (not illustrated) for forming a contact hole is formed according to the photoengraving technique. With the resist pattern used as a mask, the interlayer insulating layer II is dry-etched. According to this, the contact hole CH3 ranging from the top surface of the interlayer insulating layer II to the n⁺ region NR and the contact hole CH4 ranging from the top surface of the interlayer insulating layer II to the n⁺ guard ring dopant region NRG are formed. Then, the resist pattern is removed, for example, according to the asking.

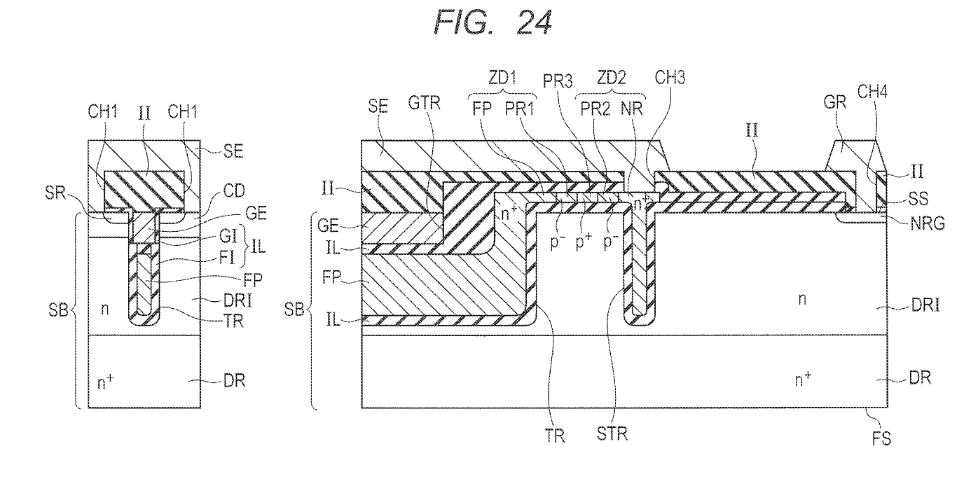

As shown in FIG. 24, the conductive layer, for example, made of aluminum is deposited on the whole surface of the second surface SS of the semiconductor substrate SB, according to the sputtering. Then, according to the photoengraving and dry etching technique, the conductive layer is patterned. Thus, the wiring layer of the gate wiring layer GIC, the source electrode SE, and the guard ring GR is formed from the conductive layer.

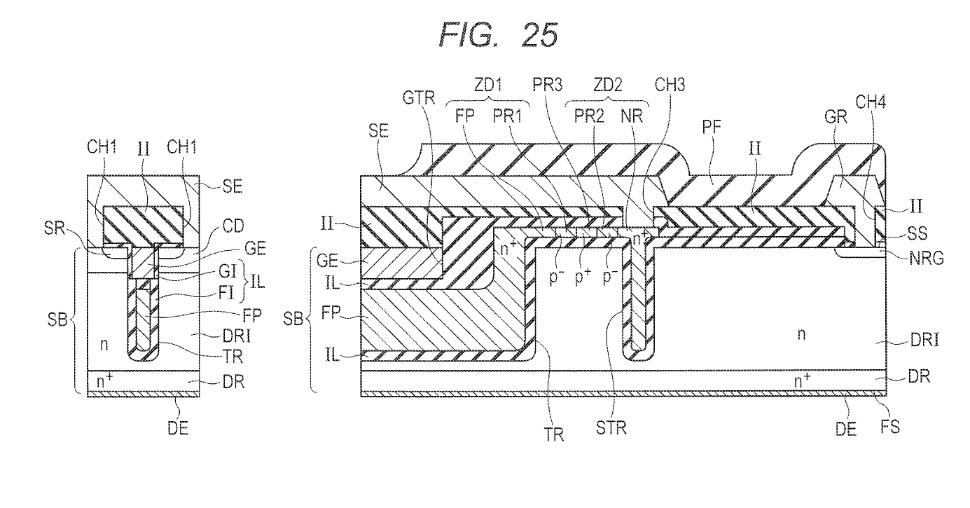

As shown in FIG. 25, a surface protective layer PF made of polyimide is formed on the wiring layer. Then, according to the photoengraving and etching technique, a pad opening portion is formed on the surface protective layer PF.

Then, the semiconductor substrate SB is ground into a predetermined thickness from the side of the first surface FS of the semiconductor substrate SB. The drain electrode DE is formed on the ground first surface FS of the semiconductor substrate SB according to the sputtering.

As mentioned above, a semiconductor device according to the embodiment is manufactured.

Next, the effects of the embodiment will be described.

In the embodiment, similarly to the structure shown in FIG. 1, the field plate electrode FP is electrically insulated from the drain region DR as shown in FIG. 3. Therefore, no through-current flows between the drain region DR and the source region SR of the MOS transistor.

In the embodiment, similarly to the structure shown in FIG. 1, the field plate electrode FP is electrically coupled to the source region SR through the Zener diode ZD1. The Zener diode ZD1 is coupled in the forward direction from the source electrode SE (or the source region SR) to the field plate electrode FP. According to this, even when a hot carrier is injected to the field plate electrode FP, the hot carrier is discharged to the source electrode SE (or the source region SR) as a leak current of the Zener diode ZD1. Therefore, the potential of the field plate electrode FP does not fluctuate over time according to the hot carrier.

In the embodiment, as shown in FIG. 3, the two Zener diodes ZD1 and ZD2 having the anode in common are electrically coupled between the field plate electrode FP and the source electrode SE (or the source region SR). The Zener diode ZD1 coupled in the forward direction between the source and the field plate generates a field plate potential. The Zener diode ZD2 coupled in the backward direction between the source and the field plate restricts the field plate potential also in the negative potential direction. According to this, the field plate insulating layer FI can be easily protected from the dielectric breakdown.

In the embodiment, the two Zener diodes ZD1 and ZD2 are formed from the conductive layer (for example, polycrystalline silicon) in common with the field plate electrode FP. Therefore, a semiconductor device can be manufactured in a small number of the manufacturing processes.

### Second Embodiment

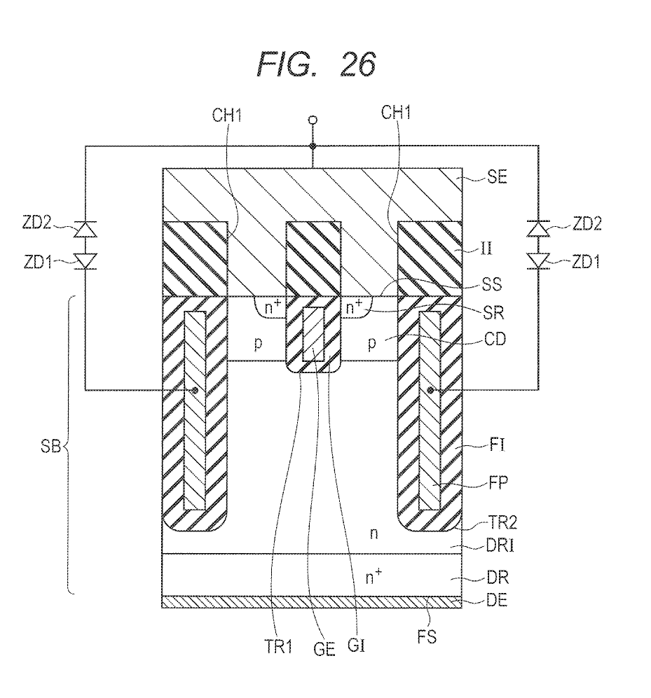

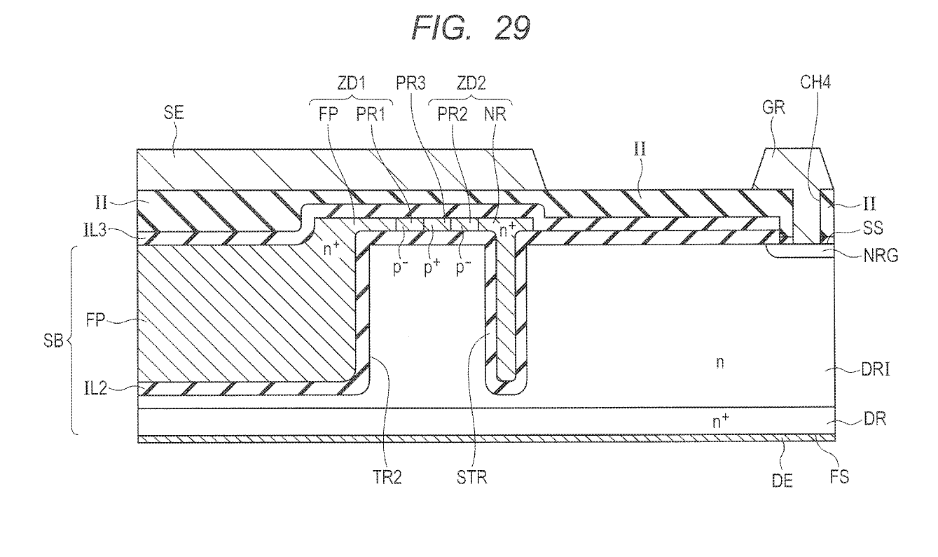

A structure of a semiconductor device according to a second embodiment will be described using FIGS. 26 to 29.

As shown in FIG. 26, the structure of the semiconductor device according to the embodiment is different from the structure of the first embodiment shown in FIG. 3 in that the field plate electrode FP and the gate electrode GE are respectively arranged in the different trenches TR1 and TR2.

In the embodiment, each of the different trenches TR1 and TR2 is formed on the second surface SS of the semiconductor substrate SB. The trench TR1 and the trench TR2 are mutually separated from each other. The depth of the trench TR1 is different from the depth of the trench TR2. The trench TR2 is formed deeper than the trench TR1.

As shown in FIG. 26, the trench TR1 is formed penetrating the channel region CD from the second surface SS of the semiconductor substrate SB and arriving at the drift region DRI. Therefore, the bottom wall of the trench TR1 is in contact with the drift region DRI. Further, the side wall of the trench TR1 is in contact with each of the channel region CD and the source region SR.

The gate electrode GE is arranged within the trench TR1. The gate insulation layer GI is arranged between the gate electrode GE and the wall surface of the trench TR1. According to this, the gate electrode GE is insulated from the channel region CD oppositely.

The trench TR2 is formed from the second surface SS of the semiconductor substrate SB, penetrating the channel region CD, arriving at the drift region DRI, and further extending deep into the drift region DRI. Therefore, a part of the side wall of the trench TR2 and the bottom wall are in contact with the drift region DRI. The other portion of the side wall of the trench TR2 is in contact with the channel region CD.

The field plate electrode FP is arranged within the trench TR2. The field plate insulating layer FI is arranged between the field plate electrode FP and the wall surface of the trench TR2. According to this, the field plate electrode FP is insulated from the drift region DRI and the channel region CD oppositely.

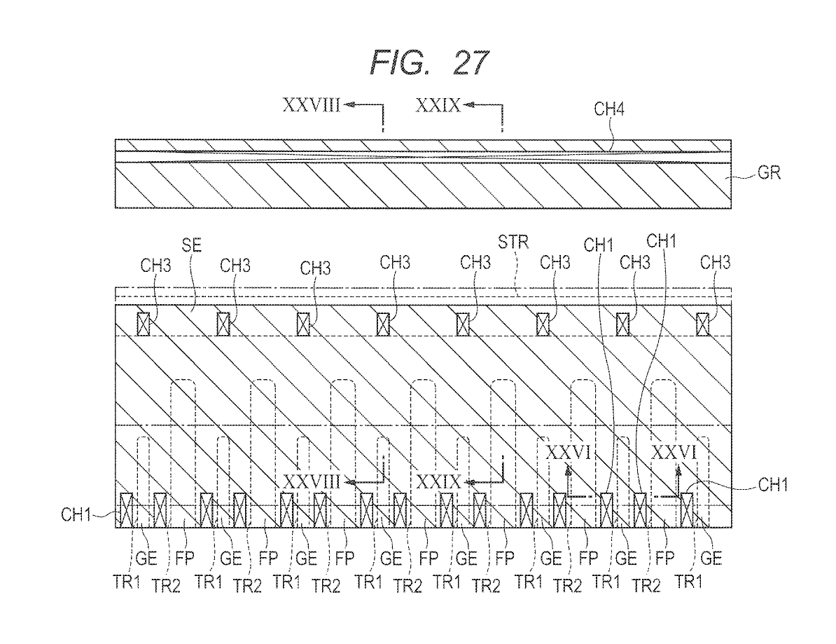

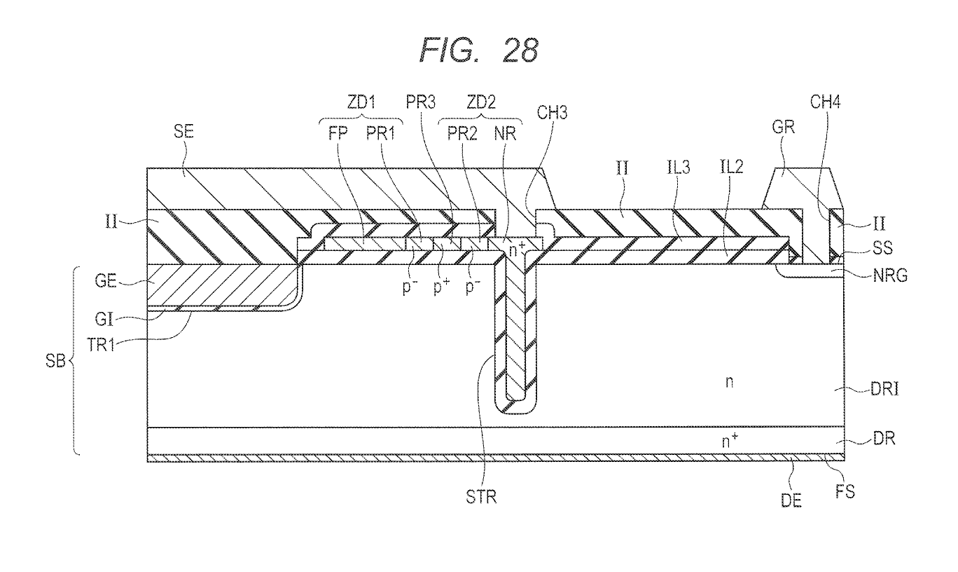

The interlayer insulating layer II is arranged on the second surface SS of the semiconductor substrate SB. The contact holes CH1 (FIG. 26), CH3 (FIGS. 27 and 28), and CH4 (FIGS. 27, 28, and 29) are formed in the interlayer insulating layer II.

The contact hole CH1 is formed ranging from the top surface of the interlayer insulating layer II to both the source region SR and the channel region CD. The contact hole CH1 arrives at the region of the second surface SS sandwiched by the trench TR1 and the trench TR2.

The source electrode SE is arranged on the interlayer insulating layer II. The source electrode SE is arranged to be electrically coupled to the source region SR and the channel region CD through the contact hole CH1.

The other structure than the above in the embodiment is substantially the same as the structure shown in FIG. 3; therefore, the same reference numerals are attached to the same elements and their description is not repeated.

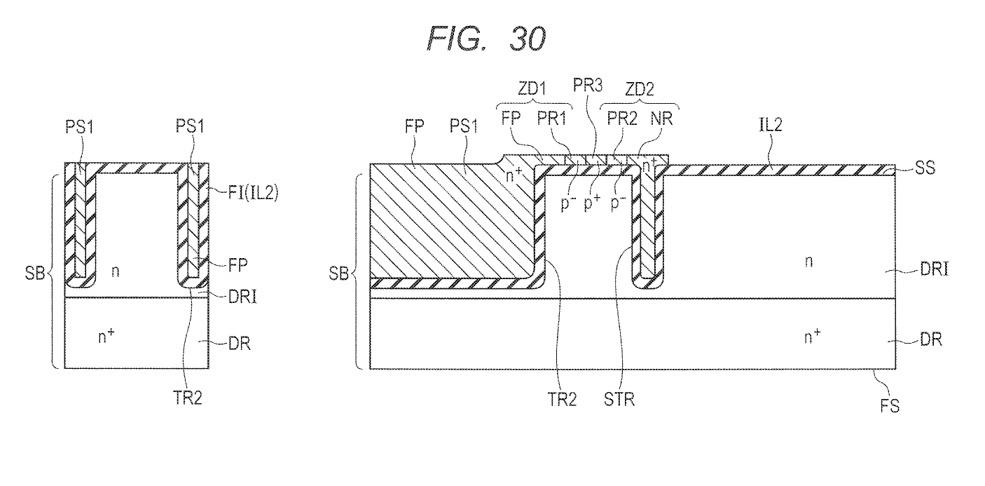

Next, a manufacturing method of the semiconductor device according to the embodiment will be described using FIGS. 30 to 32. The manufacturing method according to the embodiment has the same processes as those of the first embodiment shown in FIGS. 12 to 15. Then, as shown in FIG. 30, the doped polysilicon PS1 within the trench TR (the trench TR2 in the embodiment) is not etched deep.

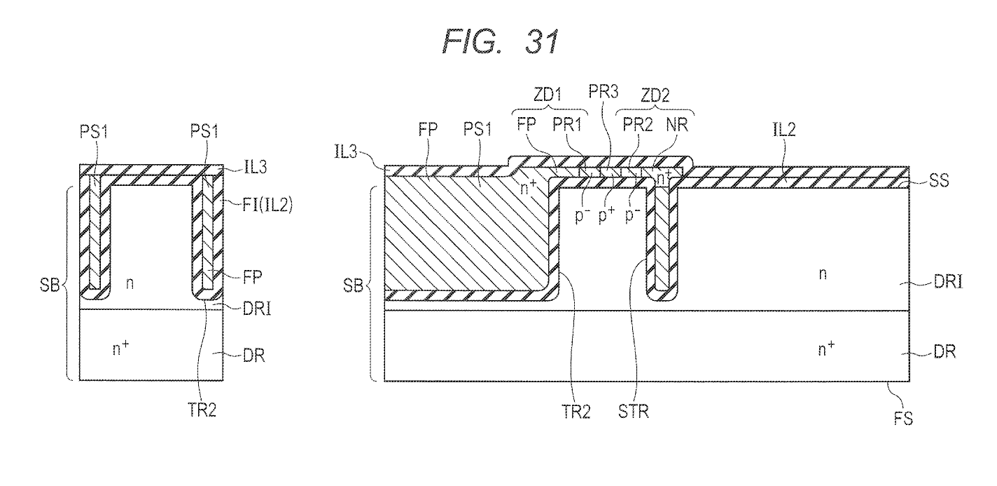

As shown in FIG. 31, the insulating layer IL3 made of, for example, oxide film is deposited on the insulating layer IL2 to cover the polycrystalline silicon layer PS1 according to the CVD.

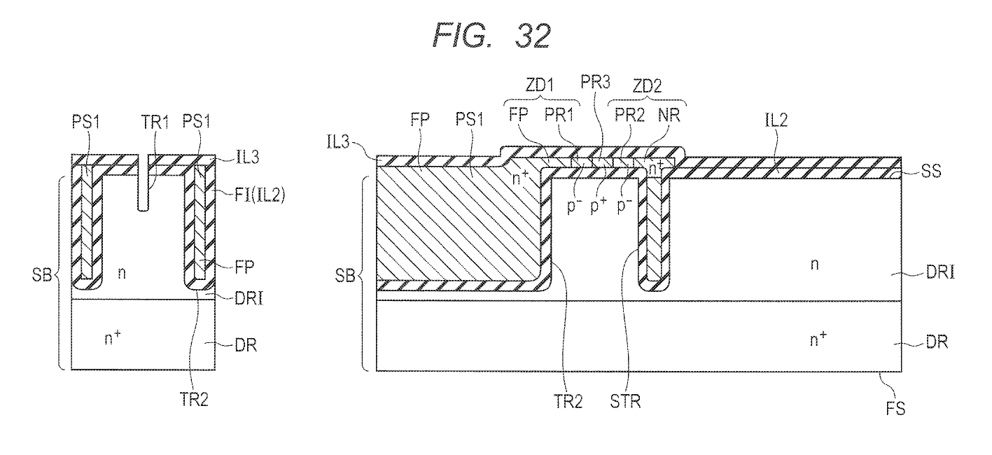

As shown in FIG. 32, a resist pattern (not illustrated) having a pattern for forming the trench TR1 is formed according to the photoengraving technique. With this resist pattern used as a mask, the insulating layers IL2 and IL3 and the semiconductor substrate SB are dry-etched. According to this, the trench TR1 is formed on the semiconductor substrate SB. Then, the resist pattern is removed, for example, according to the asking.

Thereafter, the manufacturing method according to the embodiment has the same processes as those in the first embodiment shown in FIGS. 19 to 25. According to this, the semiconductor device of the embodiment shown in FIGS. 26 to 29 is manufactured.

Next, the effects of the embodiment will be described.

In the embodiment, similarly to the structure shown in FIG. 3, the field plate electrode FP is electrically insulated from the drain region DR, as shown in FIG. 26. Therefore, no through-current flows between the drain region DR and the source region SR of the MOS transistor.

In the embodiment, similarly to the structure shown in FIG. 3, the field plate electrode FP is electrically coupled to the source electrode SE (or the source region SR) through the Zener diode ZD1, as shown in FIG. 26. The Zener diode ZD1 is coupled in the forward direction from the source electrode SE (or the source region SR) to the field plate electrode FP. According to this, even when a hot carrier is injected to the field plate electrode FP, the hot carrier is discharged to the source electrode SE (or the source region SR) as a leak current of the Zener diode ZD1. Therefore, the potential of the field plate electrode FP does not fluctuate over time according to the hot carrier.

In the embodiment, similarly to the structure shown in FIG. 3, the two Zener diodes ZD1 and ZD2 having the anode in common are electrically coupled between the field plate electrode FP and the source region SR, as shown in FIG. 26. The Zener diode ZD1 coupled in the forward direction between the source and field plate generates a field plate potential. The Zener diode ZD2 coupled in the backward direction between the source and field plate restricts the filed plate potential also in the negative potential direction. According to this, the field plate insulating layer FI can be easily protected from a dielectric breakdown.

According to the embodiment, as shown in FIG. 26, the gate electrode GE and the field plate electrode FP are respectively formed in the different trenches TR1 and TR2. According to this, the forming process (FIG. 18) of the insulating film between the gate electrode GE and the field plate electrode FP requiring a control of a precise etching amount is not necessary, which makes it easy to manufacture a semiconductor device.

According to the embodiment, a parasitic capacitance Cgf between the field plate electrode FP and the gate electrode GE becomes smaller. Accordingly, the parasitic capacitance Cgd between the gate and drain becomes smaller, hence to enable high speed switching.

### Third Embodiment

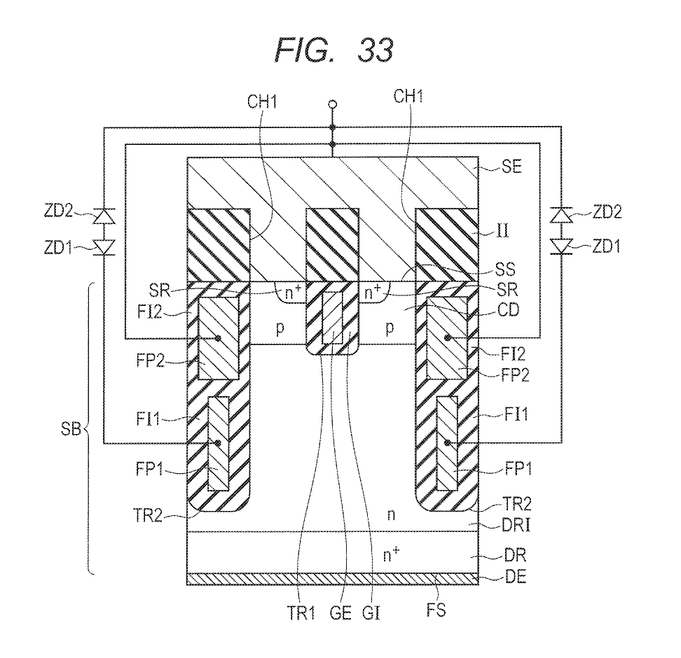

A structure of a semiconductor device according to a third embodiment will be described using FIGS. 33 to 35.

As shown in FIG. 33, the structure of the semiconductor device is different from the structure according to the second embodiment shown in FIGS. 26 to 29 in that the field plate electrode is divided into a first field plate electrode FP1 and a second field plate electrode FP2.

In the embodiment, the first field plate electrode FP1 and the second field plate electrode FP2 are arranged within the same trench TR2. The second field plate electrode FP2 is separated from the first field plate electrode FP1 and positioned nearer to the second surface SS than the first field plate electrode FP1.

The first field plate electrode FP1 is electrically coupled to the source region SR through the Zener diodes ZD1 and ZD2. The second field plate electrode FP2 is electrically coupled to the source region SR without any Zener diode.

The first field plate insulating layer FI1 is arranged between the first field plate electrode FP1 and the wall surface of the trench TR2. The second field plate insulating layer FI2 is arranged between the second field plate electrode FP2 and the wall surface of the trench TR2. The thickness of the first field plate insulating layer FI1 is more than that of the second field plate insulating layer FI2.

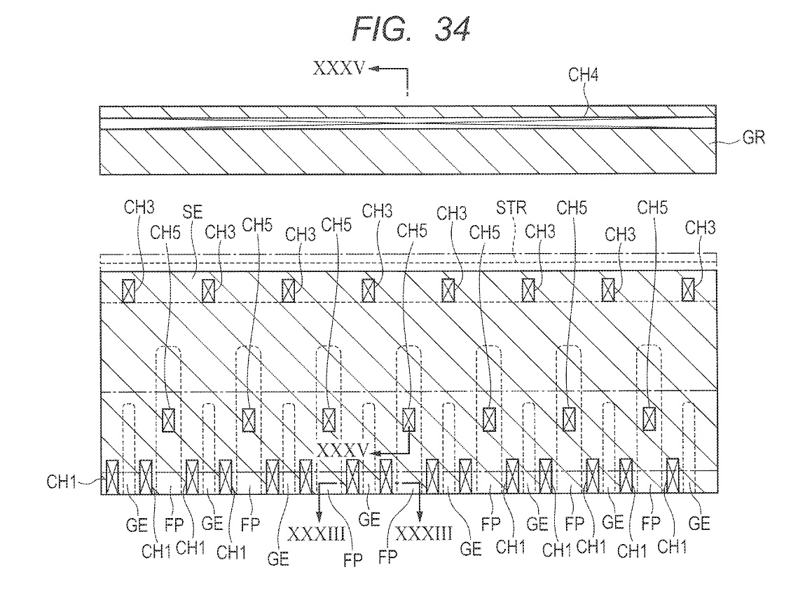

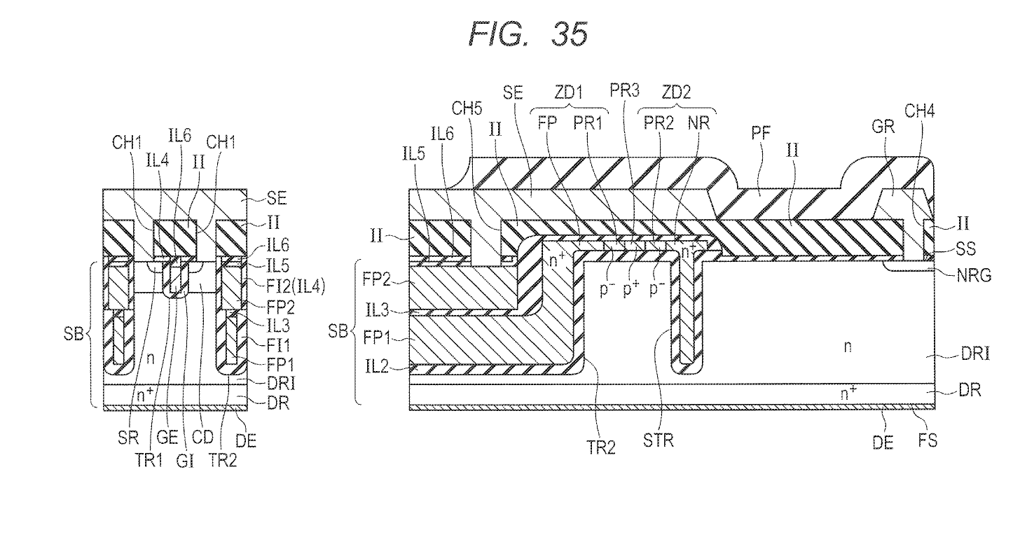

As shown in FIG. 34 and FIG. 35, the insulating layers IL5 and IL6 are arranged on the top surface of the second field plate electrode FP2. A contact hole CH5 penetrating the insulating layers IL5 and IL6 from the top surface of the interlayer insulating layer II and arriving at the second field plate electrode FP2 is formed just above the trench TR2. The source electrode SE is electrically coupled to the second field plate electrode FP2 through this contact hole CH5.

The structure of the embodiment other than the above is substantially the same as the structure of the second embodiment shown in FIGS. 26 to 29; therefore the same reference numerals are attached to the same elements and their description is not repeated.

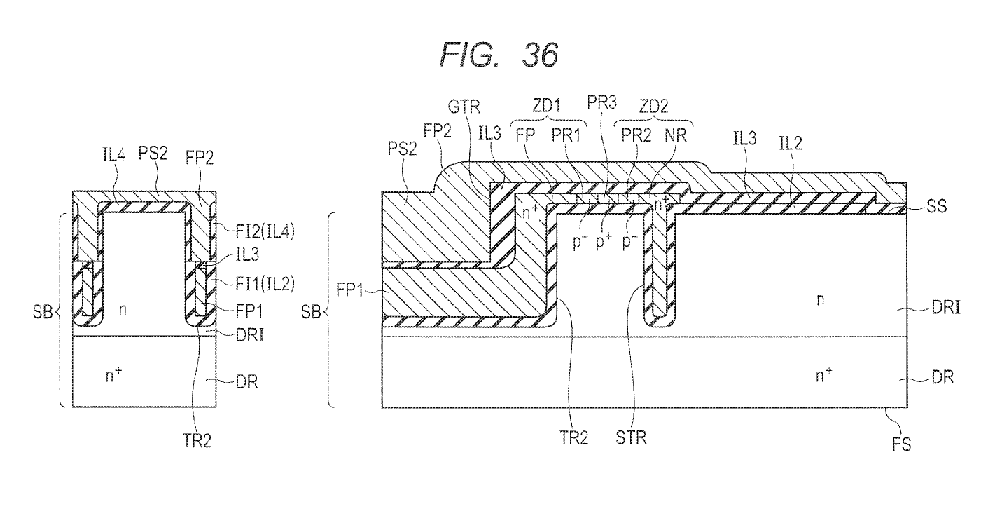

Next, a manufacturing method of the semiconductor device according to the embodiment will be described using FIGS. 36 to 43.

The manufacturing method according to the embodiment has the same processes as those of the first embodiment shown in FIGS. 12 to 18. Then, as shown in FIG. 36, the second surface SS of the semiconductor substrate SB and the wall surface of the trench TR are oxidized according to the thermal oxidization, and the insulating layer IL4, for example, made of silicon oxide film is formed. The portion of the insulating layer IL4 formed on the wall surface of the trench TR2 works as the field plate insulating layer FI2. Then, the polycrystalline silicon layer PS2 is formed to fill the trench TR2 and to cover the insulating layers IL3 and IL4. Then, the polycrystalline silicon layer PS2 is dry-etched.

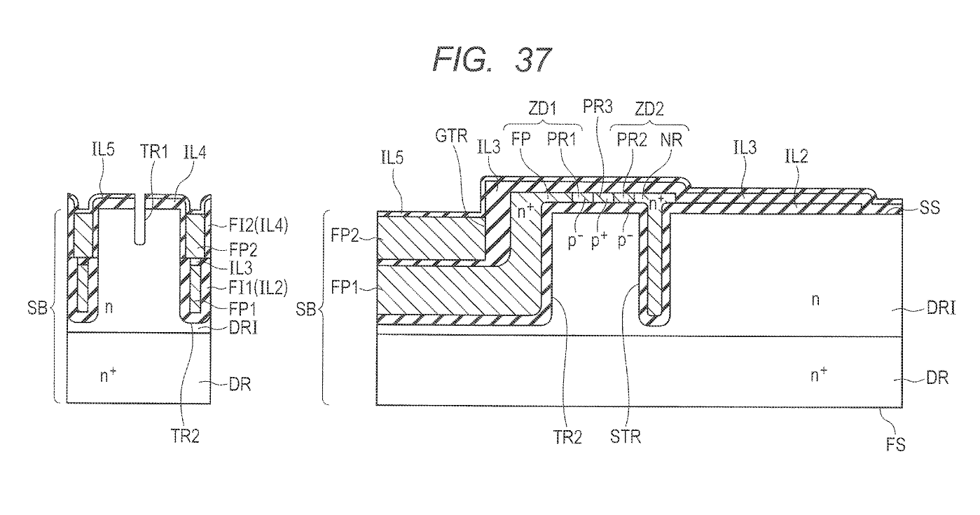

As shown in FIG. 37, the second field plate electrode FP2 is formed from the conductive layer PS2 to fill the trench TR2 (to be embedded within the concave portion GTR) according to the above dry etching. Then, the insulating layer IL5 (for example, silicon oxide film) as a mask layer for processing the trench TR1 is deposited according to the CVD. The insulating layer IL5 is patterned to have a pattern for processing the trench TR1. The insulating layer IL4 and the semiconductor substrate SB are etched with the insulating layer IL5 used as a mask. According to this, the trench TR1 is formed on the second surface SS of the semiconductor substrate SB.

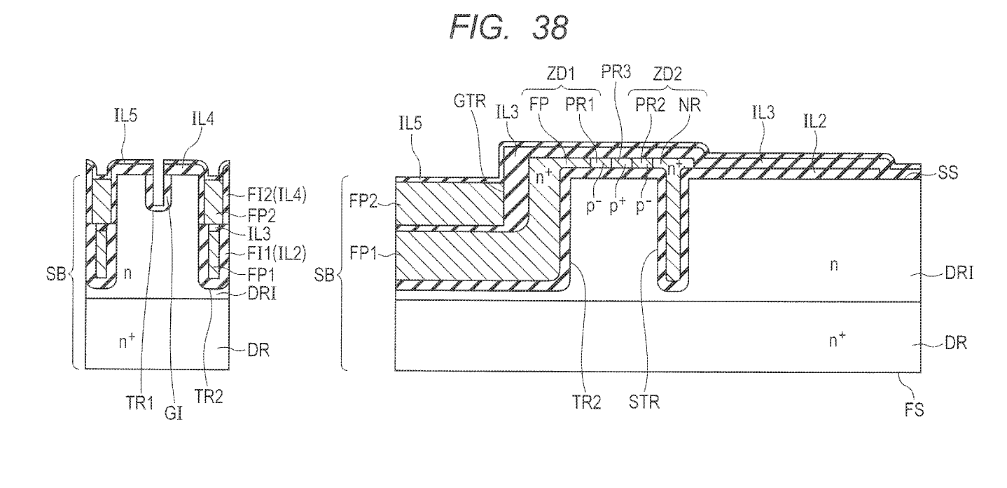

As shown in FIG. 38, the inside of the trench TR1 is thermally oxidized. According to this, the gate insulation layer GI made of silicon oxide film is formed on the inner wall of the trench TR1.

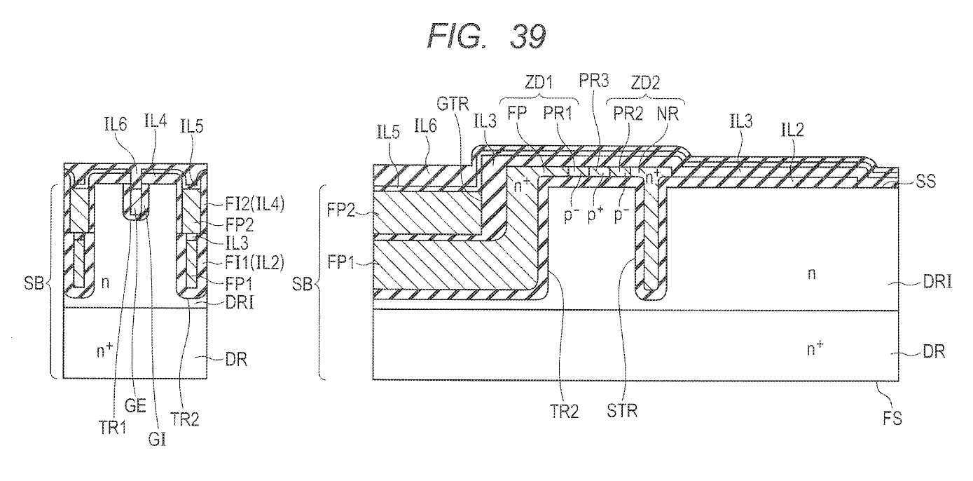

As shown in FIG. 39, the conductive layer GE, for example, made of polycrystalline silicon is formed on the insulating layer IL5 to fill the trench TR1. The conductive layer GE is dry-etched and left only within the trench TR1, to form the gate electrode GE within the trench TR1. Then, the insulating layer IL6 made of silicon oxide film is deposited on the whole surface of the second surface SS of the semiconductor substrate SB according to the CVD. The opening portion of the trench TR1 is filled with the insulating layer IL6.

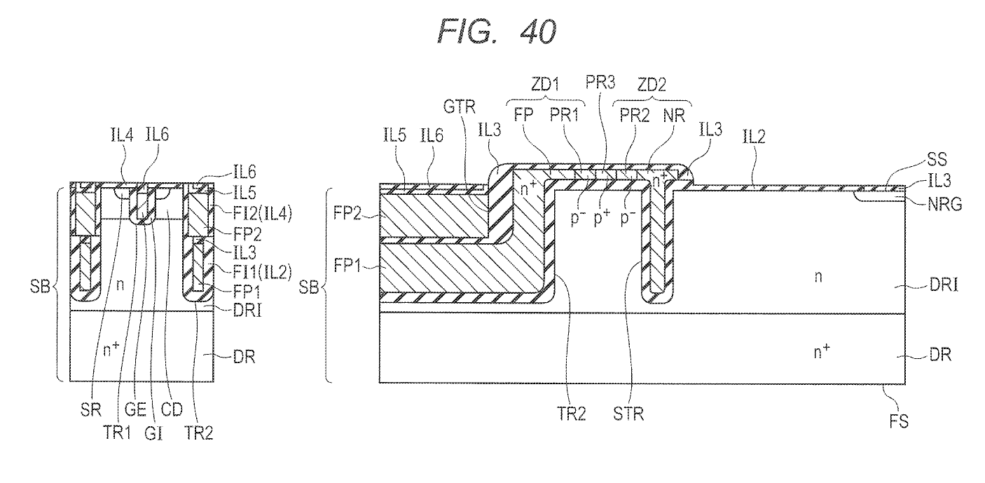

As shown in FIG. 40, the insulating layers IL6 to IL3 are dry-etched. According to this, the insulating layers IL6 to IL3 cover the second surface SS of the semiconductor substrate SB thinly. In this state, the resist pattern (not illustrated) is formed according to the photoengraving technique and with this resist pattern used as a mask, the p-type dopant is injected to the second surface SS of the semiconductor substrate SB according to the ion implantation. Thus, the channel region CD is formed on the second surface SS of the semiconductor substrate SB. This resist pattern is removed, for example, according to the asking.

Thereafter, another resist pattern (not illustrated) is formed according to the photoengraving technique and with this resist pattern used as a mask, the n-type dopant is injected to the second surface SS of the semiconductor substrate SB according to the ion implantation. As the result, the source region SR and the n⁺ guard ring dopant region NRG are formed on the second surface SS of the semiconductor substrate SB. Then, this resist pattern is also removed, for example, according to the asking.

After the above resist pattern is removed, annealing is performed to activate the dopant.

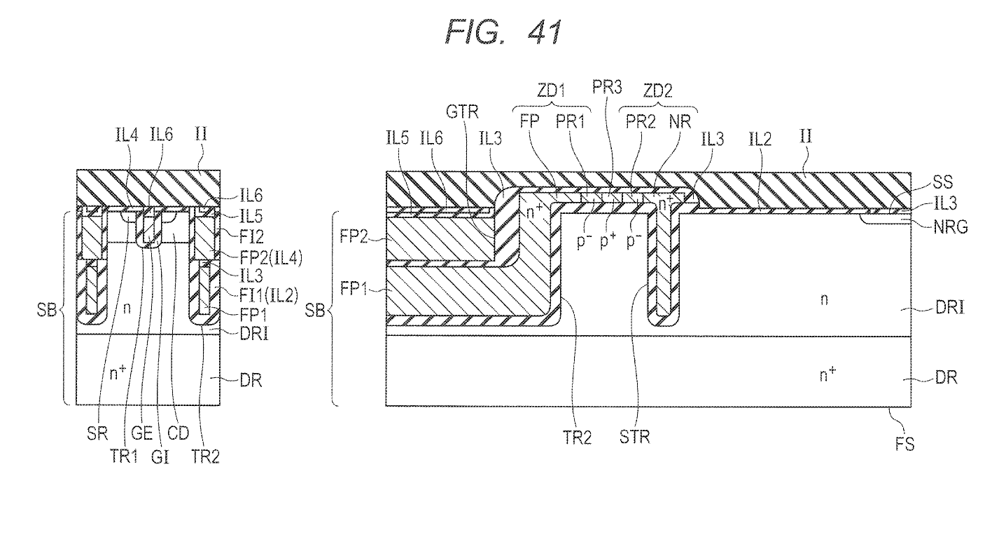

As shown in FIG. 41, the interlayer insulating layer II made of phosphorus glass is deposited on the whole surface of the second surface SS of the semiconductor substrate SB. Then, the top surface of the interlayer insulating layer II is flattened according to the CMP.

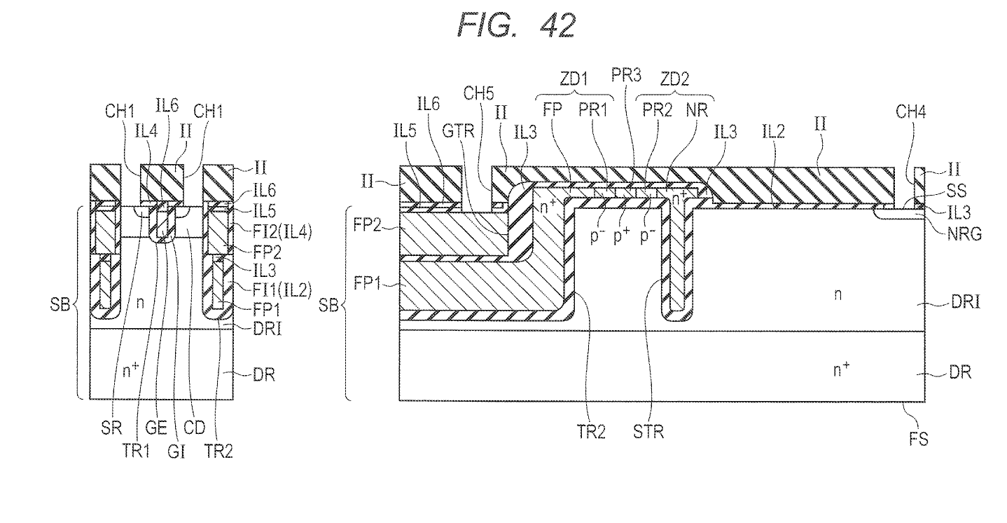

As shown in FIG. 42, a resist pattern (not illustrated) for forming a contact hole is formed according to the photoengraving technique. With this resist pattern used as a mask, the interlayer insulating layer II is dry-etched. According to this, the contact hole CH3 ranging from the top surface of the interlayer insulating layer II to the n⁺ region NR and the contact hole CH4 ranging from the top surface of the interlayer insulating layer II to the n⁺ guard ring dopant region NRG are formed.

Further, the contact hole CH1 ranging from the top surface of the interlayer insulating layer II to the source region SR and the channel region CD and the contact hole CH5 ranging from the top surface of the interlayer insulating layer II to the second field plate electrode FP2 are formed.

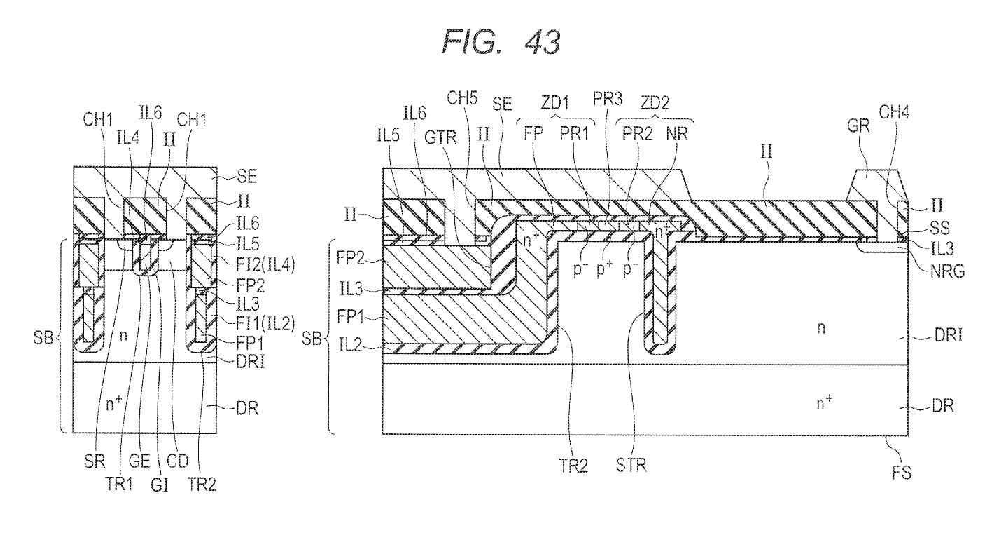

As shown in FIG. 43, the conductive layer, for example, made of aluminum is deposited on the whole surface of the second surface SS of the semiconductor substrate SB according to the sputtering. Then, the conductive layer is patterned according to the photoengraving and dry etching technique. The wiring layer of the gate wiring layer GIC, the source electrode SE, and the guard ring GR is formed from the conductive layer.

As shown in FIG. 35, the surface protective layer PF made of polyimide is formed on the wiring layer. A pad opening portion is formed on the surface protective layer PF according to the photoengraving and etching technique. The semiconductor substrate SB is ground from the side of the first surface FS into a predetermined thickness. The drain electrode DE is formed on the ground first surface FS of the semiconductor substrate SB according to the sputtering.

As mentioned above, the semiconductor device according to the embodiment shown in FIGS. 33 to 35 is manufactured.

Next, the effects of the embodiment will be described.

Similarly to the structure shown in FIG. 3, in the embodiment, the field plate electrodes FP1 and FP2 are electrically insulated from the drain region DR, as shown in FIG. 33. Therefore, no through-current flows between the drain region DR and the source region SR of the MOS transistor.

Similarly to the structure shown in FIG. 3, in the embodiment, the field plate electrode FP1 is electrically coupled to the source region SR through the Zener diode ZD1, as shown in FIG. 33. The Zener diode ZD1 is coupled in the forward direction from the source region SR to the field plate electrode FP1. Even when a hot carrier is injected to the field plate electrode FP1, the hot carrier is discharged to the source region SR as a leak current of the Zener diode ZD1. As the result, the potential of the field plate electrode FP1 does not fluctuate over time according to the hot carrier.

Similarly to the structure shown in FIG. 3, in the embodiment, the two Zener diodes ZD1 and ZD2 having the anode in common are electrically coupled between the field plate electrode FP and the source region SR, as shown in FIG. 33. The Zener diode ZD1 coupled in the forward direction between the source and the field plate generates a field plate potential. Further, the Zener diode ZD2 coupled in the backward direction between the source and the field plate restricts the field plate potential also in a negative potential direction. According to this, the field plate insulating layer FI can be easily protected from a dielectric breakdown.

In the embodiment, the gate electrode GE and the field plate electrodes FP1 and FP2 are respectively arranged within the different trenches TR1 and TR2, as shown in FIG. 33. Similarly to the second embodiment, it is not necessary to form the insulating layer between the gate electrode GE and the field plate electrodes FP1 and FP2 requiring a precious control of etching amount, which makes it easy to manufacture the semiconductor device.

In the embodiment, the potential of the second field plate electrode FP2 facing the gate electrode GE is fixed to a source potential, as shown in FIG. 33. Therefore, compared with the structure where the potential of the field plate electrode FP is easily variable according to the drain potential like the second embodiment shown in FIG. 26, the parasitic capacitance Cgf can be decreased further in the embodiment.

Further, in the embodiment, the field plate electrode is divided into the first and second field plate electrodes FP1 and FP2, as shown in FIG. 33. This makes it possible to adjust the length in the depth direction of the first and second field plate electrodes FP1 and FP2 and the thickness of the field plate insulating layers FI1 and FI2 individually. Compared with the first and the second embodiments, the embodiment can further enlarge the breakdown voltage between the drain and source (resistance can be further decreased with the same breakdown voltage).

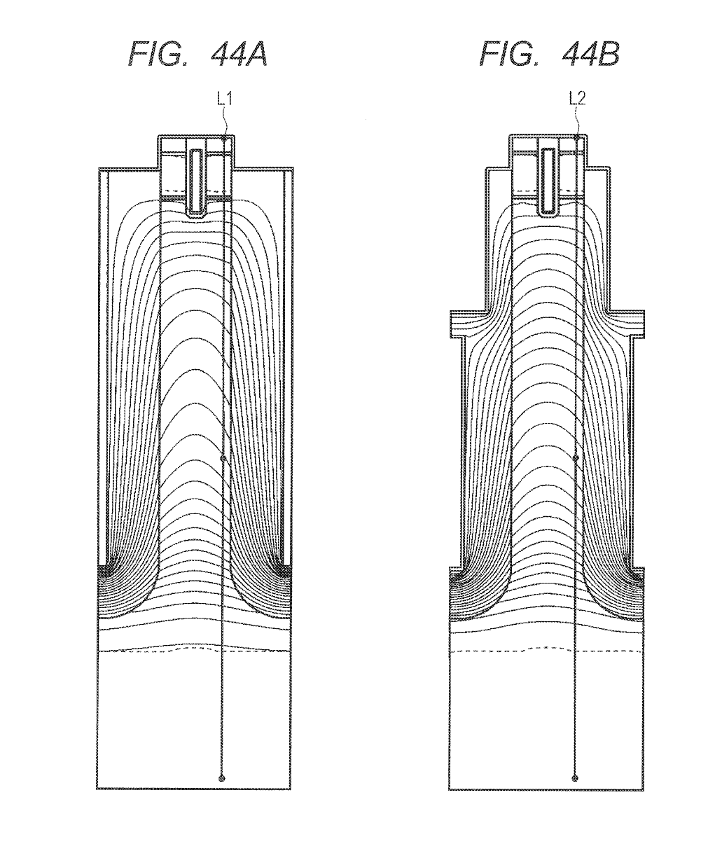

The inventors et al. have examined the potential distribution (isoelectric line) within the cell of the MOS transistor in the state with the same voltage applied to the drain in each structure of the second embodiment and the third embodiment. The results are shown in FIGS. 44A and 44B.

FIG. 44A shows the potential distribution in the structure of the second embodiment and FIG. 44B shows the potential distribution in the structure of the third embodiment. As shown in FIG. 44A, in the structure of the second embodiment, the interval of the isoelectric lines on the side near the drain becomes the minimum and it is getting wider according as closer to the source. The interval between the isoelectric lines becomes widest at the position having the depth 3 μm and less from the second surface SS of the semiconductor substrate SB and becomes narrower in the vicinity of the channel junction.

In the structure of the third embodiment, as shown in FIG. 44B, the interval between the isoelectric lines is similarly the minimum on the side near the drain; however, the interval of the isoelectric lines according as closer to the source fluctuates more modestly and becomes almost even compared to the second embodiment. The interval of the isoelectric lines indicates the electric field intensity. Therefore, the results of FIGS. 44A and 44B indicate that the electric field intensity distribution in the drift region when a drain voltage is applied becomes more even in the structure of the third embodiment.

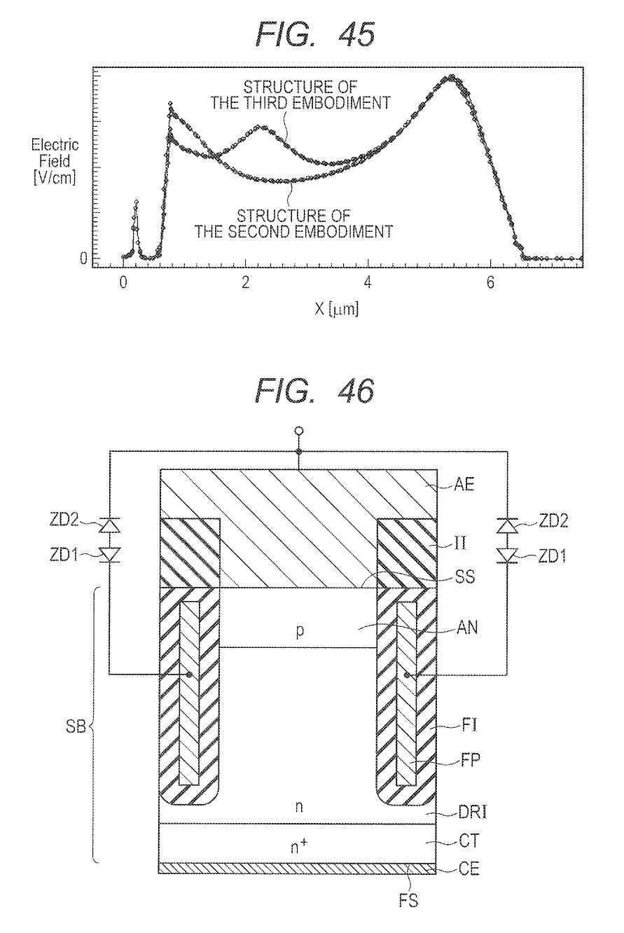

FIG. 45 shows the electric field intensity distribution along the line L1 in FIG. 44A and the line L2 in FIG. 44B. As shown in FIG. 45, in the structure of the third embodiment, the electric field intensity is stronger in the vicinity of the lower end of the second field plate FP2 than in the structure of the second embodiment. Therefore, according to the third embodiment, the electric field intensity distribution can be uniformed further and a dielectric breakdown can be avoided from occurring even at a higher voltage.

### Fourth Embodiment

The MOS transistor has been described in the first to the third embodiments; however, the structure in the above first to third embodiments can be also applied to a diode. Also when the structure of the above first to third embodiments is applied to a diode, a diode having a lower conductive resistance and a higher breakdown voltage can be obtained, similarly to the MOS transistor. Hereinafter, the structure of applying the above embodiments to a diode will be described.

FIG. 46 is a cross-sectional view showing the structure with the configuration of FIG. 26 applied to a diode. The structure shown in FIG. 46 is different from the structure shown in FIG. 26 mainly in that the gate electrode and the source region are omitted.

As shown in FIG. 46, the field plate diode includes a diode and a field plate electrode FP (first field plate electrode).

The diode mainly includes a cathode region CT (first dopant region), a drift region DRI, and an anode region AN.

The cathode region CT is the n-type dopant region (n⁺ dopant region) and arranged on the first surface FS of the semiconductor substrate SB. The anode region AN is the p-type dopant region and arranged on the second surface SS of the semiconductor substrate SB.

The drift region DRI is arranged between the cathode region CT and the anode region AN within the semiconductor substrate SB. The drift region DRI is the n-type dopant region having a lower n-type dopant concentration than the cathode region CT. The drift region DRI and the anode region AN form a pn junction.

The semiconductor substrate SB includes a trench TR extending from the second surface SS into the drift region DRI. The drift region DRI and the anode region AN are in contact with the wall surface of the trench TR.

The cathode electrode CE is arranged on the first surface FS of the semiconductor substrate SB. The cathode electrode CE is in contact with the cathode region CT and electrically coupled to the cathode region CT. The anode electrode AE is arranged on the second surface SS of the semiconductor substrate SB. The anode electrode AE is in contact with the anode region AN and electrically coupled to the anode region AN.

The field plate electrode FP is arranged within the trench TR. The field plate electrode FP faces the drift region DRI with the field plate insulating layer FI sandwiched therebetween. According to this, the field plate electrode FP is insulated from the drift region DRI oppositely.

There are the Zener diodes ZD1 and ZD2 electrically coupled between the anode region AN and the field plate electrode FP. The Zener diode ZD1 is coupled in the forward direction from the source region SR to the field plate electrode FP. The Zener diode ZD2 is coupled in the backward direction of the above; from the field plate electrode FP to the source region SR.

Specifically, the cathode of the Zener diode ZD1 is electrically coupled to the field plate electrode FP. The anode of the Zener diode ZD1 is electrically coupled to the anode of the Zener diode ZD2. The cathode of the Zener diode ZD2 is electrically coupled to the anode region AN through the anode electrode AE.

The structure shown in FIG. 46 is manufactured passing through the same manufacturing processes as shown in FIGS. 12 to 15 and the same manufacturing processes as shown in FIGS. 30 and 31, hence to form the anode region AN, the interlayer insulating layer II, and the anode electrode AE.

According to the structure shown in FIG. 46, the substantially same effects as those of the structure shown in FIG. 26 can be obtained.

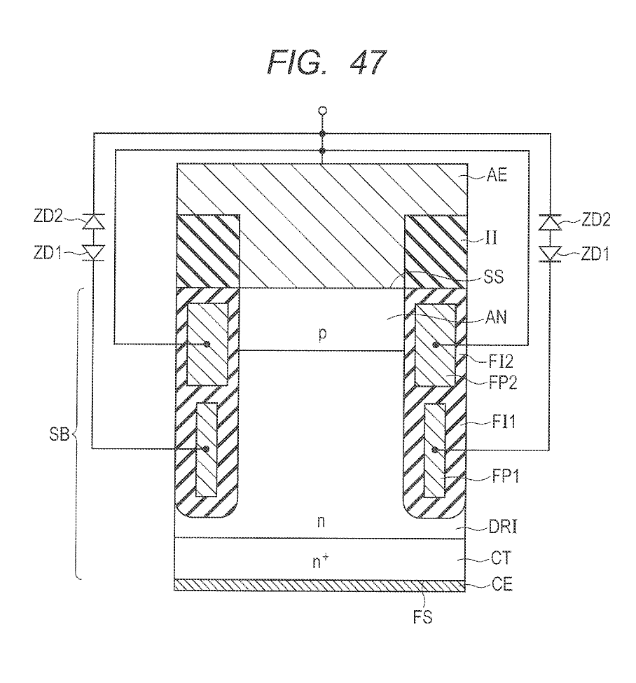

FIG. 47 shows the structure of dividing the field plate electrode FP in the structure of FIG. 46 into the first field plate electrode FP1 and the second field plate electrode FP2. As shown in FIG. 47, the first field plate electrode FP1 and the second field plate electrode FP2 are arranged within the same trench TR2. The second field plate electrode FP2 is separated from the first field plate electrode FP1 and positioned nearer to the second surface SS than the first field plate electrode FP1.

The first field plate electrode FP1 is electrically coupled to the source region SR through the Zener diodes ZD1 and ZD2. The second field plate electrode FP2 is electrically coupled to the source region SR without any Zener diode.

The first field plate insulating layer FI1 is arranged between the first field plate electrode FP1 and the wall surface of the trench TR2. According to this, the first field plate electrode FP1 is electrically insulated from the drift region DRI oppositely.

The second field plate insulating layer FI2 is arranged between the second field plate electrode FP2 and the wall surface of the trench TR2. According to this, the second field plate electrode FP2 is electrically insulated from the drift region DRI and the anode region AN oppositely. The thickness of the first field plate insulating layer FI1 is more than that of the second field plate insulating layer FI2.

The structure of FIG. 47 other than the above is substantially the same as the structure shown in FIG. 46; therefore, the same reference numerals are attached to the same elements and their description is not repeated.

The structure shown in FIG. 47 is manufactured passing through the same manufacturing processes shown in FIGS. 12 to 20, to form the anode region AN, the interlayer insulating layer II, and the anode electrode AE.

According to the structure shown in FIG. 47, the substantially same effects as those of the structure shown in FIG. 33 can be obtained.

Alternatively, only one Zener diode ZD as shown in FIG. 1 may be electrically coupled between the anode region AN and the field plate electrode FP (or FP1), in the structure of FIGS. 46 and 47. Further, in the structure of FIGS. 26 and 33, only one Zener diode ZD as shown in FIG. 1 may be electrically coupled between the source region SR and the field plate electrode FP (or FP1).

### (Others)

Although the field plate type MOS transistor and diode have been described in the above embodiments, the structure of the above embodiments can be applied also to a field plate IGBT. Specifically, the structure of the above first to third embodiments can be applied to the field plate IGBT by replacing the drain region in the first to third embodiments with a p-type collector region.

Although the n channel MOS transistor has been described in the above first to third embodiments, the invention may be applied to a p channel MOS transistor. Similarly to this, the structure of the above embodiments may be applied to the diode and IGBT having a reverse conductivity type.

Although the MOS transistor has been described in the first to the third embodiments, needless to say, the structure of the above embodiments can be also applied to a Metal Insulation Semiconductor (MIS) transistor.

In addition to the above, further the following appendixes are disclosed.

### APPENDIX 1

A manufacturing method of a semiconductor device including the following steps of: forming a first dopant region of a first conductivity type as a cathode region, on a first surface of a semiconductor substrate having the first surface and a second surface facing each other; forming a drift region of the first conductivity type having a lower dopant concentration of the first conductivity type than the first dopant region, on the first dopant region at the side of the above second surface within the semiconductor substrate; forming a trench extending from the second surface into the drift region, in the semiconductor substrate; forming a first field plate electrode within the trench to be electrically insulated from the first dopant region and insulated from the drift region oppositely; forming a second dopant region of a second conductivity type as an anode, on the second surface of the semiconductor substrate to sandwich the drift region with the first dopant region; and forming a Zener diode electrically coupled between the second dopant region and the first field plate electrode, in which the Zener diode is coupled in the forward direction from the second dopant region to the first field plate electrode.

### APPENDIX 2

The manufacturing method according to the appendix 1, in which the first field plate electrode and the Zener diode are formed from the same conductive layer.

### APPENDIX 3

The manufacturing method according to the appendix 1, further including a step of forming a second field plate electrode within the same trench as the first field plate electrode, in which the second field plate electrode is separated from the first field plate electrode, positioned nearer to the second surface than the first field plate electrode, and electrically coupled to the second dopant region without the Zener diode.

As set forth hereinabove, the invention made by the inventors et al. has been specifically described based on the above embodiments; however, the invention is not restricted to the embodiments but needless to say, various modifications are possible without departing from its spirit.

1. A semiconductor device comprising:
a semiconductor substrate having a first surface and a second surface facing each other;
a first dopant region of a first conductivity type as a drain region arranged over the first surface of the semiconductor substrate;
a second dopant region of the first conductivity type as a source region arranged over the second surface of the semiconductor substrate; and
a drift region of the first conductivity type that is arranged between the first dopant region and the second dopant region within the semiconductor substrate and has a lower dopant concentration of the first conductivity type than the first dopant region,
wherein the semiconductor substrate includes a trench extending from the second surface into the drift region,
a first field plate electrode that is arranged within the trench to be electrically insulated from the first dopant region and insulated from the drift region oppositely, and
a first Zener diode that is electrically coupled between the second dopant region and the first field plate electrode,
the first Zener diode being coupled in a forward direction from the second dopant region to the first field plate electrode.

2. The device according to claim 1, further comprising:
a channel region of a second conductivity type that is arranged between the second dopant region and the drift region within the semiconductor substrate, and
a gate electrode that is insulated from the channel region oppositely and electrically insulated from the first field plate electrode.

3. The device according to claim 2,
wherein the first field plate electrode and the gate electrode are arranged within the same trench.

4. The device according to claim 2,
wherein the trench includes a first trench portion and a second trench portion separated from the first trench portion, and
wherein the first field plate electrode is arranged within, the first trench portion and the gate electrode is arranged within the second trench portion.

5. A semiconductor device comprising:
a semiconductor substrate having a first surface and a second surface facing each other;
a first dopant region of a first conductivity type as a cathode region arranged over the first surface of the semiconductor substrate;
a second dopant region of a second conductivity type as an anode region arranged over the second surface of the semiconductor substrate; and
a drift region of the first conductivity type that is arranged between the first dopant region and the second dopant region within the semiconductor substrate and has a lower dopant concentration of the first conductivity type than the first dopant region,
wherein the semiconductor substrate includes a trench extending from the second surface into the drift region,
a first field plate electrode that is arranged within the trench to be electrically insulated from the first dopant region and insulated from the drift region oppositely; and
a first Zener diode that is electrically coupled between the second, dopant region and the first field plate electrode,
the first Zener diode being coupled in a forward direction from the second dopant region to the first field plate electrode.

6. The device according to claim 5,
wherein the second dopant region forms a pn junction together with the drift region.

7. The device according to claim 5, further comprising:
a second field plate electrode that is arranged within the same trench as the first field plate electrode,
wherein the second field plate electrode is separated from the first field plate electrode, positioned nearer to the second surface than the first field plate electrode, and electrically coupled to the second dopant region without the first Zener diode.

8. The device according to claim 1, further comprising:
a second Zener diode that is electrically coupled between the first Zener diode and the second dopant region,
wherein the second Zener diode is coupled in a backward direction, that is, from the first field plate electrode to the second dopant region.

9. The device according to claim 1,
wherein the first Zener diode is arranged within a conductive layer in common with the first field plate electrode.

10. A manufacturing method of a semiconductor device comprising the following steps of:
forming a first dopant region of a first conductivity type as a drain region over a first surface of a semiconductor substrate having the first surface and a second surface facing each other;
forming a drift region of the first conductivity type having a lower dopant concentration of the first conductivity type than the first dopant region, over the first dopant region at a side of the second surface within the semiconductor substrate;
forming a trench extending from the second surface into the drift region, in the semiconductor substrate;
forming a first field plate electrode within the trench, to be electrically insulated from the first dopant region and insulated froth the drift region oppositely;
forming a second dopant region of the first conductivity type as a source region over the second surface of the semiconductor substrate, to sandwich the drift region with the first dopant region; and
forming a Zener diode that is electrically coupled between the second dopant region and the first field plate electrode;
wherein the Zener diode is coupled in a forward direction from the second dopant region to the first field plate electrode.

11. The method according to claim 10,
wherein the first field plate electrode and the Zener diode are formed from a same conductive layer.

12. The method according to claim 10, further comprising:
a step of forming a second field plate electrode within the same trench as the first field plate electrode,
wherein the second field plate electrode is separated from the first field plate electrode, positioned nearer to the second surface than the first field plate electrode, and electrically coupled to the second dopant region without the Zener diode.

13. The device according to claim 5, further comprising:
a second Zener diode that is electrically coupled between the first Zener diode and the second dopant region,
wherein the second Zener diode is coupled in a backward direction, that is, from the first field plate electrode to the second dopant region.

14. The device according to claim 5,
wherein the first Zener diode is arranged within a conductive layer in common with the first field plate electrode.
